(19) United States
(12) Patent Application Publication
(10) Pub. No.: US 2026/0107839 A1
(43) Pub. Date: Apr. 16, 2026

(54) SEMICONDUCTOR STRUCTURES, SEMICONDUCTOR DEVICES, COMPUTING-IN-MEMORY DEVICES, ELECTRONIC APPARATUS, AND OPERATION METHODS THEREOF

(71) Applicant: Yangtze Memory Technologies Holding Co., Ltd., Wuhan (CN)

(72) Inventors: Yu ZHANG, Wuhan (CN); Lei Jin, Wuhan (CN); Feng Xu, Wuhan (CN); Da Li, Wuhan (CN); Zongliang Huo, Wuhan (CN)

(21) Appl. No.: 19/236,824

(22) Filed: Jun. 12, 2025

Related U.S. Application Data
(63) Continuation of application No. PCT/CN2025/088886, filed on Apr. 14, 2025.

(30) Foreign Application Priority Data
Oct. 10, 2024 (CN) 202411412243.6

(51) Int. Cl. H01L 25/18; H01L 23/00; H01L 23/31; H10B 12/00; H10B 41/20; H10B 41/30; H10B 41/40; H10B 43/20; H10B 43/30; H10B 43/40; H10B 80/00; H10D 80/30

(52) U.S. Cl. CPC H10W 90/00; H10B 12/482; H10B 12/50; H10B 41/30; H10B 41/40; H10B 43/30; H10B 43/40; H10B 80/00; H10D 80/30; H10B 41/20; H10B 43/20; H10W 74/114; H10W 80/312; H10W 80/327; H10W 90/20; H10W 90/792

(57) ABSTRACT

A disclosed semiconductor device comprises a first semiconductor structure comprising an analog-to-digital converter circuit and a data processing circuit; and a second semiconductor structure comprising a memory array and a peripheral circuit coupled to the memory array; wherein the analog-to-digital converter circuit is coupled with the memory array and configured to convert analog computation information based on a first operation performed by the memory array into digital information, and the data processing circuit is coupled with the analog-to-digital converter circuit and configured to perform a second operation based on the digital information.

### CROSS-REFERENCE TO RELATED APPLICATIONS

This application is a continuation of International Application No. PCT/CN2025/088886, filed on Apr. 14, 2025, which claims the benefit of priority to Chinese Application No. 202411412243.6, filed on Oct. 10, 2024, both of which are incorporated herein by reference in their entireties.

### BACKGROUND

The present disclosure relates to semiconductor structures, semiconductor devices, computing-in-memory (CIM) devices, electronic apparatus, and operation methods thereof.

In the traditional von Neumann computing architecture, memory and processors are separate, and data is transferred between them through a data bus. During execution, the processor first retrieves data from memory, processes it, and then writes the updated data back to memory. This frequent data transfer results in significant power consumption and time overhead. Additionally, the limited memory bandwidth constrains the processor's speed, greatly impacting computational performance. With the rise of big data and artificial intelligence (AI) applications, the bottlenecks of the von Neumann architecture are becoming increasingly evident.

To overcome these limitations, CIM chip architectures have emerged. The fundamental concept of CIM is embedding computational functionality within the memory itself, allowing direct execution of logic operations within the memory. This approach reduces data transfer between memory and processors, decreases power consumption, and enhances computing performance, enabling the construction of high-computational-power, high-bandwidth, and high-energy-efficiency computing systems.

### SUMMARY

One aspect of the present application provides a semiconductor device, comprising: a first semiconductor structure comprising an analog-to-digital converter circuit and a data processing circuit; and a second semiconductor structure comprising a memory array and a peripheral circuit coupled to the memory array; wherein the analog-to-digital converter circuit is coupled with the memory array and configured to convert analog computation information based on a first operation performed by the memory array into digital information, and the data processing circuit is coupled with the analog-to-digital converter circuit and configured to perform a second operation based on the digital information.

In some implementations, the second semiconductor structure comprises: a first sub-semiconductor structure including the memory array; and a second sub-semiconductor structure including the peripheral circuit; the first sub-semiconductor structure and the second sub-semiconductor structure are bonded together.

In some implementations, the memory array is located between the first semiconductor structure and the peripheral circuit.

In some implementations, the first semiconductor structure is bonded with the second semiconductor structure.

In some implementations, the first semiconductor structure is hybrid bonded with the second semiconductor structure.

In some implementations, the analog-to-digital converter circuit is coupled to the memory array through bonding contacts that interconnect the first semiconductor structure and the second semiconductor structure.

In some implementations, the first semiconductor structure further comprises bit lines; the second semiconductor structure further includes first interconnect structures extending through the memory array and coupled with the bit lines; and the memory array is coupled to the analog-to-digital converter circuit through the bit lines, the first interconnect structures, and the bonding contacts.

In some implementations, the first semiconductor structure further includes a source layer located between the memory array and the first semiconductor structure, and coupled to source ends of memory strings in the memory array; and the memory array is coupled to the analog-to-digital converter circuit through the source layer and the bonding contacts.

In some implementations, the source layer includes isolation structures dividing the source layer into a plurality of sub-source regions; and each of the plurality of sub-source regions is independently connected to the analog-to-digital converter circuit through at least one of the bonding contacts.

In some implementations, the isolation structures comprise first isolation structures each extending along a word line direction and second isolation structures each extending along a bit line direction.

In some implementations, the second semiconductor structure further includes second interconnect structures each extending through the memory array and connecting to a corresponding one of the plurality of sub-source regions; and the peripheral circuit is coupled to the sub-source regions through the second interconnect structures.

In some implementations, the first semiconductor structure further comprises a switch control circuit comprising a plurality of switch groups each being coupled to a corresponding one of the plurality of the sub-source regions; and each switch group comprises a first switch between the corresponding one of the plurality of the sub-source regions and the analog-to-digital converter circuit, and a second switch between the corresponding one of the plurality of the sub-source regions and the peripheral circuit.

In some implementations, the second semiconductor structure further includes third interconnect structures each extending through the memory array and coupled between the second switch and the peripheral circuit.

In some implementations, when the first switch is closed and the second switch is open, the first switch generates a signal transmission path between the corresponding one of the plurality of the sub-source region and the analog-to-digital converter circuit through at least one of the bonding contacts; when the first switch is open and the second switch is closed, the second switch generates a signal transmission path between the corresponding one of the plurality of the sub-source region and the peripheral circuit through at least one of the third interconnect structures.

In some implementations, the first semiconductor structure further comprises: a first interface circuit configured to output a computation result of the second operation performed by the data processing circuit; and a controller configured to control the memory array to perform the first operation through the peripheral circuit.

In some implementations, the first sub-semiconductor structure further comprises fourth interconnect structures each extending through the memory array; the second sub-semiconductor structure further comprises a second interface circuit coupled with the peripheral circuit; and wherein the controller is coupled to the peripheral circuit through the first interface circuit, the fourth interconnect structures, and the second interface circuit.

In some implementations, a first lateral size of the analog-to-digital converter circuit is less than a second lateral size of the peripheral circuit; and a bandwidth of the analog-to-digital converter circuit is at least 25 GB/s.

In some implementations, the semiconductor device further comprises: two second semiconductor structures arranged laterally side by side; or a plurality of second semiconductor structures arranged laterally in an array form.

In some implementations, the first operation comprises a multiply-accumulate operation; and the second operation comprises one or more of compensation, activation, shift, or pooling operations.

In some implementations, the memory array comprises at least one of a three-dimensional NAND memory array and a three-dimensional DRAM array.

Another aspect of the present disclosure provides a semiconductor structure, comprising: a first sub-semiconductor structure comprising: a memory array configured to perform a first operation, and a bonding layer on a first side of the memory array and configured to output analog computation information of the first operation to an analog-to-digital converter circuit in an external semiconductor structure through the bonding layer; and a second sub-semiconductor structure on a second side of the memory array opposite to the first side, and comprising a peripheral circuit coupled with the memory array and configured to control the memory array.

In some implementations, the first sub-semiconductor structure further comprises: bit lines coupled with the memory array; and first interconnect structures extending through the memory array and coupled between the bit lines and the bonding layer.

In some implementations, the first sub-semiconductor structure further comprises a source layer coupled source ends of memory strings in the memory array and the bonding layer.

In some implementations, the source layer includes isolation structures dividing the source layer into a plurality of sub-source regions, each being independently coupled with a corresponding bonding contact in the bonding layer.

In some implementations, the isolation structures comprise first isolation structures each extending along a word line direction and second isolation structures each extending along a bit line direction.

In some implementations, the semiconductor structure further comprises: second interconnect structures each extending through the memory array and being coupled between a corresponding one of the plurality of sub-source regions and the peripheral circuit.

In some implementations, the first operation comprises a multiply-accumulate operation.

In some implementations, the memory array comprises at least one of a three-dimensional NAND memory array and a three-dimensional DRAM array.

Another aspect of the present disclosure provides a semiconductor device, comprising: a first sub-semiconductor structure comprising: a memory array configured to perform a first operation, and bit lines coupled with the memory array and configured to transmit analog computation information of the first operation, a bonding layer on a first side of the first sub-semiconductor structure, and configured to output the analog computation information of to an analog-to-digital converter circuit in an external semiconductor device through the bonding layer, and first interconnect structures extending through the memory array and configured to transmit the analog computation information from the bit lines to the bonding layer; and a second sub-semiconductor structure on a second side of the first sub-semiconductor structure opposite to the first side, and comprising a peripheral circuit coupled with the memory array and configured to control the memory array.

In some implementations, the semiconductor device further comprises: the first operation comprises a multiply-accumulate operation.

In some implementations, the memory array comprises at least one of a three-dimensional NAND memory array and a three-dimensional DRAM array.

Another aspect of the present disclosure provides a semiconductor device, comprising: a bonding layer configured to be bonded to an external semiconductor structure including a memory array; an analog-to-digital converter circuit configured to: receive analog computation information from the memory array through the bonding layer, and convert the analog computation information into digital information; and a data processing circuit coupled with the analog-to-digital converter circuit and configured to perform a second operation based on the digital information.

In some implementations, the semiconductor device further comprises: a switch control circuit comprising a plurality of switch groups each being coupled between the analog-to-digital converter circuit and the bonding layer.

In some implementations, each switch group comprises: a first switch between the analog-to-digital converter circuit and a first bonding contact in the bonding layer, wherein the first bonding contact is configured to be bonded with a third bonding contact that is in the external semiconductor structure and coupled with one sub-source region of the memory array; and a second switch between the first switch and a second bonding contact in the bonding layer, wherein the second bonding contact is configured to be bonded with a fourth bonding contact that is in the external semiconductor structure and coupled with a peripheral circuit of the memory array.

In some implementations, the semiconductor device further comprises: when the first switch is closed and the second switch is open, the analog computation information is transformed from the one sub-source region of the memory array through the first bonding contact, the third bonding contact, and the first switch; when the first switch is open and the second switch is closed, the analog computation information is transformed from the one sub-source region of the memory array through the peripheral circuit, the second bonding contact, the fourth bonding contact, and the second switch.

In some implementations, the semiconductor device further comprises: a first interface circuit configured to output a computation result of the second operation performed by the data processing circuit; and a controller configured to control the memory array.

In some implementations, a bandwidth of the analog-to-digital converter circuit is at least 25 GB/s.

Another aspect of the present disclosure provides a semiconductor device, comprising: a first semiconductor structure comprising an analog-to-digital converter circuit and a data processing circuit; and a second semiconductor structure comprising: a first sub-semiconductor structure comprising a memory array, and a second sub-semiconductor structure comprising a peripheral circuit coupled to the memory array; wherein the analog-to-digital converter circuit is coupled with the memory array and configured to convert analog computation information based on a first operation performed by the memory array into digital information, and the data processing circuit is coupled with the analog-to-digital converter circuit and configured to perform a second operation based on the digital information.

In some implementations, the first sub-semiconductor structure is located between the first semiconductor structure and the second sub-semiconductor structure.

In some implementations, the first semiconductor structure is bonded with the second semiconductor structure; and the first sub-semiconductor structure is bonded with the second sub-semiconductor structure.

In some implementations, the first semiconductor structure is hybrid bonded with the second semiconductor structure; and the first sub-semiconductor structure is hybrid bonded with the second sub-semiconductor structure.

In some implementations, the analog-to-digital converter circuit is coupled to the memory array through bonding contacts that interconnect the first semiconductor structure and the second semiconductor structure.

In some implementations, the first semiconductor structure further comprises bit lines; the second semiconductor structure further includes first interconnect structures extending through the memory array and coupled with the bit lines; and the memory array is coupled to the analog-to-digital converter circuit through the bit lines, the first interconnect structures, and the bonding contacts.

In some implementations, the first semiconductor structure further includes a source layer located between the memory array and the first semiconductor structure, and coupled to source ends of memory strings in the memory array; and the memory array is coupled to the analog-to-digital converter circuit through the source layer and the bonding contacts.

In some implementations, the source layer includes isolation structures dividing the source layer into a plurality of sub-source regions; and each of the plurality of sub-source regions is independently connected to the analog-to-digital converter circuit through at least one of the bonding contacts.

In some implementations, the isolation structures comprise first isolation structures each extending along a word line direction and second isolation structures each extending along a bit line direction.

In some implementations, the semiconductor device further comprises: the second semiconductor structure further includes second interconnect structures each extending through the memory array and connecting to a corresponding one of the plurality of sub-source regions; and the peripheral circuit is coupled to the sub-source regions through the second interconnect structures.

In some implementations, the first semiconductor structure further comprises a switch control circuit comprising a plurality of switch groups each being coupled to a corresponding one of the plurality of the sub-source regions; and each switch group comprises a first switch between the corresponding one of the plurality of the sub-source regions and the analog-to-digital converter circuit, and a second switch between the corresponding one of the plurality of the sub-source regions and the peripheral circuit.

In some implementations, the second semiconductor structure further includes third interconnect structures each extending through the memory array and coupled between the second switch and the peripheral circuit.

In some implementations, when the first switch is closed and the second switch is open, the first switch generates a signal transmission path between the corresponding one of the plurality of the sub-source region and the analog-to-digital converter circuit through at least one of the bonding contacts; when the first switch is open and the second switch is closed, the second switch generates a signal transmission path between the corresponding one of the plurality of the sub-source region and the peripheral circuit through at least one of the third interconnect structures.

In some implementations, the first semiconductor structure further comprises: a first interface circuit configured to output a computation result of the second operation performed by the data processing circuit; and a controller configured to control the memory array to perform the first operation through the peripheral circuit.

In some implementations, the first sub-semiconductor structure further comprises fourth interconnect structures each extending through the memory array; the second sub-semiconductor structure further comprises a second interface circuit coupled with the peripheral circuit; and wherein the controller is coupled to the peripheral circuit through the first interface circuit, the fourth interconnect structures, and the second interface circuit.

In some implementations, a first lateral size of the analog-to-digital converter circuit is less than a second lateral size of the peripheral circuit; and a bandwidth of the analog-to-digital converter circuit is at least 25 GB/s.

In some implementations, the semiconductor device further comprises: two second semiconductor structures arranged laterally side by side; or a plurality of second semiconductor structures arranged laterally in an array form.

In some implementations, the first operation comprises a multiply-accumulate operation; and the second operation comprises one or more of compensation, activation, shift, or pooling operations.

In some implementations, the memory array comprises at least one of a three-dimensional NAND memory array and a three-dimensional DRAM array.

Another aspect of the present disclosure provides a method for operating a semiconductor device, comprising: performing a first operation by a memory array in a second semiconductor structure to obtain analog computation information, wherein the second semiconductor structure further includes a peripheral circuit coupled to the memory array; converting the analog computation information obtained from the memory array performing the first operation into digital information using an analog-to-digital converter circuit in a first semiconductor structure, wherein the first semiconductor structure and the second semiconductor structure are bonded together; performing a second operation based on the digital information using a data processing circuit in the first semiconductor structure.

In some implementations, the first operation comprises a multiply-accumulate operation; and the second operation comprises one or more of compensation, activation, shift, or pooling operations.

In some implementations, the method further comprises: in response to an execution command for the first operation, controlling a first switch to close to output the analog computation information to the analog-to-digital converter circuit; wherein the first semiconductor structure further includes a plurality of sub-source regions of the memory array; the first semiconductor structure further comprises a switch control circuit comprising a plurality of switch groups each being coupled to a corresponding one of the plurality of the sub-source regions; and each switch group comprises the first switch between the corresponding one of the plurality of the sub-source regions and the analog-to-digital converter circuit, and a second switch between the corresponding one of the plurality of the sub-source regions and the peripheral circuit.

In some implementations, the method further comprises: in response to an erase command, a program command, or a read command, controlling the second switch to close to output a control voltage to the corresponding one of the sub-source regions.

Another aspect of the present disclosure provides a packaging structure, comprising: a packaging substrate, a semiconductor device disposed on the packaging substrate, the semiconductor device comprising: a first semiconductor structure comprising an analog-to-digital converter circuit and a data processing circuit, and a second semiconductor structure comprising a memory array and a peripheral circuit coupled to the memory array, wherein the analog-to-digital converter circuit is coupled with the memory array and configured to convert analog computation information based on a first operation performed by the memory array into digital information, and the data processing circuit is coupled with the analog-to-digital converter circuit and configured to perform a second operation based on the digital information; and a molding layer encapsulates the semiconductor device.

In some implementations, the second semiconductor structure comprises: a first sub-semiconductor structure including the memory array; and a second sub-semiconductor structure including the peripheral circuit; the first sub-semiconductor structure and the second sub-semiconductor structure are bonded together.

In some implementations, the memory array is located between the first semiconductor structure and the peripheral circuit.

In some implementations, the first semiconductor structure is bonded with the second semiconductor structure.

In some implementations, the first semiconductor structure is hybrid bonded with the second semiconductor structure.

In some implementations, the analog-to-digital converter circuit is coupled to the memory array through bonding contacts that interconnect the first semiconductor structure and the second semiconductor structure.

In some implementations, the first semiconductor structure further comprises bit lines; the second semiconductor structure further includes first interconnect structures extending through the memory array and coupled with the bit lines; and the memory array is coupled to the analog-to-digital converter circuit through the bit lines, the first interconnect structures, and the bonding contacts.

In some implementations, the first semiconductor structure further includes a source layer located between the memory array and the first semiconductor structure, and coupled to source ends of memory strings in the memory array; and the memory array is coupled to the analog-to-digital converter circuit through the source layer and the bonding contacts.

In some implementations, the source layer includes isolation structures dividing the source layer into a plurality of sub-source regions; and each of the plurality of sub-source regions is independently connected to the analog-to-digital converter circuit through at least one of the bonding contacts.

In some implementations, the isolation structures comprise first isolation structures each extending along a word line direction and second isolation structures each extending along a bit line direction.

In some implementations, the second semiconductor structure further includes second interconnect structures each extending through the memory array and connecting to a corresponding one of the plurality of sub-source regions; and the peripheral circuit is coupled to the sub-source regions through the second interconnect structures.

In some implementations, the first semiconductor structure further comprises a switch control circuit comprising a plurality of switch groups each being coupled to a corresponding one of the plurality of the sub-source regions; and each switch group comprises a first switch between the corresponding one of the plurality of the sub-source regions and the analog-to-digital converter circuit, and a second switch between the corresponding one of the plurality of the sub-source regions and the peripheral circuit.

In some implementations, the second semiconductor structure further includes third interconnect structures each extending through the memory array and coupled between the second switch and the peripheral circuit.

In some implementations, when the first switch is closed and the second switch is open, the first switch generates a signal transmission path between the corresponding one of the plurality of the sub-source region and the analog-to-digital converter circuit through at least one of the bonding contacts; when the first switch is open and the second switch is closed, the second switch generates a signal transmission path between the corresponding one of the plurality of the sub-source region and the peripheral circuit through at least one of the third interconnect structures.

In some implementations, the first semiconductor structure further comprises: a first interface circuit configured to output a computation result of the second operation performed by the data processing circuit; and a controller configured to control the memory array to perform the first operation through the peripheral circuit.

In some implementations, the first sub-semiconductor structure further comprises fourth interconnect structures each extending through the memory array; the second sub-semiconductor structure further comprises a second interface circuit coupled with the peripheral circuit; and wherein the controller is coupled to the peripheral circuit through the first interface circuit, the fourth interconnect structures, and the second interface circuit.

In some implementations, a first lateral size of the analog-to-digital converter circuit is less than a second lateral size of the peripheral circuit; and a bandwidth of the analog-to-digital converter circuit is at least 25 GB/s.

In some implementations, the semiconductor device further comprises: two second semiconductor structures arranged laterally side by side; or a plurality of second semiconductor structures arranged laterally in an array form.

In some implementations, the first operation comprises a multiply-accumulate operation; and the second operation comprises one or more of compensation, activation, shift, or pooling operations.

In some implementations, the memory array comprises at least one of a three-dimensional NAND memory array and a three-dimensional DRAM array.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a structural diagram of a semiconductor device, according to some implementations of the present disclosure.

FIG. 2 illustrates a structural diagram of a semiconductor structure, according to some implementations of the present disclosure.

FIG. 3 illustrates a distribution diagram of memory cells within a semiconductor structure, according to some implementations of the present disclosure.

FIG. 4 illustrates an exemplary configuration of a semiconductor structure including a peripheral circuit, according to some implementations of the present disclosure.

FIG. 5 illustrates a cross-sectional view of a memory array comprising memory strings, according to some implementations of the present disclosure.

FIG. 6 illustrates a schematic diagram of a semiconductor structure including a memory array and a peripheral circuit, according to some implementations of the present disclosure.

FIG. 7 illustrates another schematic diagram of a semiconductor structure including a memory array and a peripheral circuit, according to some implementations of the present disclosure.

FIG. 8 illustrates a circuit diagram of applying input voltages to a memory block through top selection lines, according to some implementations of the present disclosure.

FIG. 9 illustrates a circuit diagram of multiple memory strings connected to a single bit line, according to some implementations of the present disclosure.

FIG. 10 illustrates another structural configuration of a semiconductor device, according to some other implementations of the present disclosure.

FIG. 11 illustrates yet another structural configuration of a semiconductor device, according to some other implementations of the present disclosure.

FIG. 12A illustrates a top-down schematic view of a portion of a semiconductor structure including a memory array, according to some implementations of the present disclosure.

FIG. 12B illustrates a top-down schematic view of a portion of a semiconductor structure including a memory array, according to some other implementations of the present disclosure.

FIG. 13A illustrates yet another structural configuration of a semiconductor device, according to some other implementations of the present disclosure.

FIG. 13B illustrates yet another structural configuration of a semiconductor device, according to some other implementations of the present disclosure.

FIG. 14A illustrates yet another structural configuration of a semiconductor device, according to some other implementations of the present disclosure.

FIG. 14B illustrates yet another structural configuration of a semiconductor device, according to some other implementations of the present disclosure.

FIG. 14C illustrates yet another structural configuration of a semiconductor device, according to some other implementations of the present disclosure.

FIG. 15 illustrates a flowchart of an operational process of a semiconductor device, according to some implementations of the present disclosure.

The present disclosure will be described with reference to the accompanying drawings.

### DETAILED DESCRIPTION

The technical solutions in the implementations of the present disclosure will be clearly and completely described below in conjunction with the implementations of the present disclosure and the accompanying drawings. Obviously, the described implementations are only a part of the implementations of the present disclosure, rather than all implementations. Based on the implementations in the present disclosure, all other implementations obtained by those of ordinary skill in the art without creative effort fall within the scope of protection of the present disclosure.

In the following description, numerous specific details are provided to offer a more thorough understanding of the present disclosure. However, it will be apparent to those skilled in the art that the present disclosure can be implemented without one or more of these details. In other instances, to avoid confusion with the present disclosure, some technical features well-known in the art are not described; that is, not all features of actual implementations are described here, nor are well-known functions and structures described in detail.

In the drawings, the sizes of layers, regions, elements, and their relative sizes may be adjusted for illustrative purposes. Throughout, the same reference numerals denote the same elements.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. In addition, the term “based on” may be understood as not necessarily intended to convey an exclusive set of factors and may, instead, allow for existence of additional factors not necessarily expressly described, again, depending at least in part on context.

It should be understood that when an element or layer is referred to as being “on,” “adjacent to,” “connected to,” or “coupled to” another element or layer, it may be directly on, adjacent to, connected to, or coupled to the other element or layer, or intervening elements or layers may be present. Conversely, when an element is referred to as being “directly on,” “directly adjacent to,” “directly connected to,” or “directly coupled to” another element or layer, no intervening elements or layers are present. It should be understood that although the terms first, second, third, etc., may be used to describe various elements, components, regions, layers, and/or sections, these elements, components, regions, layers, and/or sections should not be limited by these terms. These terms are only used to distinguish one element, component, region, layer, or section from another element, component, region, layer, or section. Thus, without departing from the teachings of the present disclosure, a first element, component, region, layer, or section discussed below may be referred to as a second element, component, region, layer, or section. When a second element, component, region, layer, or section is discussed, it does not necessarily imply the existence of a first element, component, region, layer, or section in the present disclosure.

Spatial relationship terms such as “under,” “below,” “beneath,” “underneath,” “above,” “over,” etc., may be used herein for convenience of description to describe the relationship of one element or feature to other elements or features as shown in the drawings. It should be understood that, in addition to the orientations shown in the drawings, these spatial relationship terms are intended to encompass different orientations of the device in use or operation. For example, if a device in the drawings is flipped, elements or features described as “below” or “beneath” or “under” other elements or features would then be oriented “above” the other elements or features. Thus, the exemplary terms “below,” “beneath,” and “under” may encompass both orientations of above and below. The device may be otherwise oriented (rotated 90 degrees or other orientations), and the spatial descriptors used herein should be interpreted accordingly.

The terminology used herein is for the purpose of describing specific implementations only and is not intended to limit the present disclosure. As used herein, the singular forms “a,” “an,” and “the” are intended to include the plural forms as well, unless the context clearly indicates otherwise. It should also be understood that the terms “comprises” and/or “includes,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

To thoroughly understand the present disclosure, detailed steps and detailed structures will be provided in the following description to explain the technical solutions of the present disclosure. Preferred implementations of the present disclosure are described in detail below; however, in addition to these detailed descriptions, the present disclosure may also have other implementations.

In the traditional von Neumann computing architecture, memory and processors are separate, and data is transferred between them through a data bus. During execution of commands, the processor first retrieves data from memory, processes it, and then writes the updated data back to memory. This frequent data transfer results in significant power consumption and time overhead. Additionally, the limited memory bandwidth constrains the processor's processing speed to the memory access speed, greatly impacting computational performance. With the rise of big data and artificial intelligence (AI) applications, the processing of massive data volumes has made the bottlenecks of the von Neumann computing architecture increasingly prominent. To address the bottlenecks of the traditional von Neumann computing architecture, computing-in-memory (CIM) chip architectures have emerged. The fundamental concept of CIM is to embed computational functionality within the memory itself and directly utilize the memory for logical operations, thereby reducing the amount and distance of data transfer between memory and processors. This approach lowers power consumption while improving computational performance, offering the potential to construct computing systems with high computational power, high bandwidth, and high energy efficiency.

CIM chips leverage their inherent physical properties to simultaneously possess storage and computational capabilities. The storage capability refers to the ability of different memories to store values by altering their conductance based on their physical properties. The computational capability refers to the ability to construct an array of memory devices and, based on Ohm's Law and Kirchhoff's Law, perform vector-matrix multiplication computations within a certain timeframe. CIM chips include, but are not limited to: Static Random Access Memory (SRAM), NAND flash memory, and Dynamic Random Access Memory (DRAM). Among these, NAND flash memory is a non-volatile memory with large capacity, making it a widely studied subject in CIM chips. The following will provide an introduction to NAND flash memory-related content.

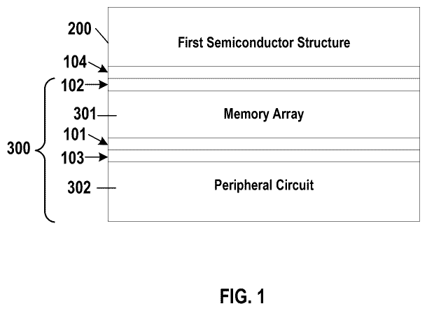

The present disclosure provides a semiconductor device. FIG. 1 is a structural diagram of a semiconductor device according to some implementations of the present disclosure. Referring to FIG. 1, the semiconductor device includes a first semiconductor structure 200 and a second semiconductor structure 300; the first semiconductor structure 200 and the second semiconductor structure 300 are bonded together; wherein the first semiconductor structure 200 includes an analog-to-digital converter (ADC) circuit and a data processing circuit; the second semiconductor structure 300 includes a memory array 301 for performing a first operation and at least a portion of peripheral circuit 302 coupled to the memory array 301. The analog-to-digital converter (ADC) circuit is configured to convert analog computation information obtained from the memory array 301 performing the first operation into digital information; the data processing circuit is configured to perform a second operation on the digital information.

In some implementations, the first semiconductor structure 200 and the second semiconductor structure 300 are located in different planes and stacked with respect to each other. Additionally, the memory array 301 and the peripheral circuit 302 within the second semiconductor structure 300 can be located in different planes and stacked with respect to each other, thereby reducing the planar size of the semiconductor device.

In some implementations, the first semiconductor structure 200 and the second semiconductor structure 300 can be formed in parallel on different substrates. For example, the first semiconductor structure 200 is formed on a first substrate, the memory array 301 is formed on a second substrate, and the peripheral circuit 302 is formed on a third substrate. Then, various bonding techniques, such as hybrid bonding or transfer bonding, are used to stack them together.

In some implementations of the present disclosure, by vertically integrating the first semiconductor structure 200 and the second semiconductor structure 300, and vertically separating the first semiconductor structure 200, the memory array 301, and the peripheral circuit 302 into different planes, the chip size can be reduced, and storage density can be increased.

In some implementations of the present disclosure, the second semiconductor structure 300 includes a first sub-semiconductor structure on which the memory array 301 is formed and a second sub-semiconductor structure on which at least a portion of the peripheral circuit 302 is formed. In some implementations, a portion of the peripheral circuit is formed on the second sub-semiconductor structure, while another portion is formed on the first sub-semiconductor structure. In other words, the peripheral circuit of the memory array can be divided into two parts: one part is formed together with the memory array on the first sub-semiconductor structure, and the other part is formed on the second sub-semiconductor structure. In other implementations, the peripheral circuit can be entirely formed on the second sub-semiconductor structure.

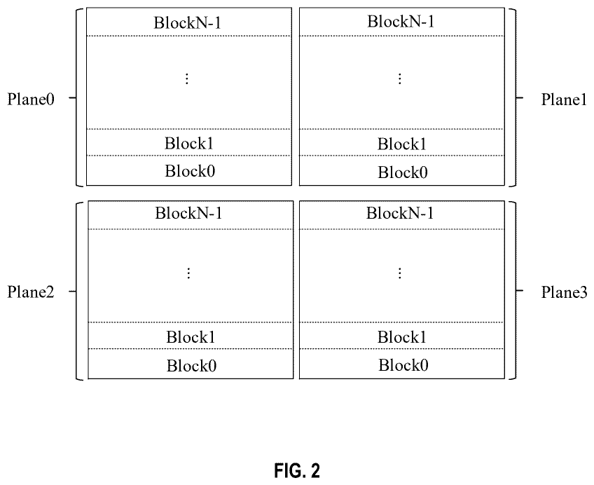

FIG. 2 illustrates an exemplary structural diagram of a second semiconductor structure, where the second semiconductor structure is described using a three-dimensional NAND memory as an example. As shown in FIG. 2, the memory array may include multiple planes (e.g., Plane0, Plane1, Plane2, and Plane3, totaling four planes), each plane including multiple banks, and each bank including multiple blocks. In some implementations, a portion of the peripheral circuit is formed on the second sub-semiconductor structure, while another portion is formed on the first sub-semiconductor structure. In other words, the first sub-semiconductor structure may include the memory array and a portion of the peripheral circuit. For example, in implementations of the present disclosure, components of the peripheral circuit, such as a page buffer, may be formed on the first sub-semiconductor structure.

In some other implementations, the peripheral circuit may be entirely formed on the second sub-semiconductor structure. It should be noted that the implementations of the present disclosure use the example where the peripheral circuit is entirely formed on the second sub-semiconductor structure for illustration.

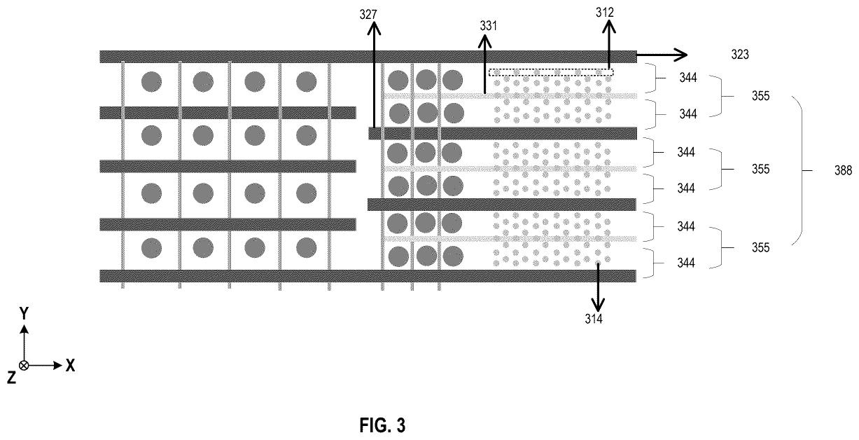

FIG. 3 illustrates an exemplary distribution diagram of memory cells within a second semiconductor structure. As shown in FIG. 3, the memory array is composed of several rows 312 of memory cells arranged in parallel and staggered, aligned with gate isolation structures (GLS). Every four rows of memory cells are separated by gate isolation structures and select gate isolation structures 331. Each row 312 of memory cells includes multiple memory strings 308 arranged along the X direction. The figure shows one memory cell in each memory string, with the remaining memory cells stacked along the Z direction relative to this cell. Here, the select gate isolation structures may be a top select gate isolation structures (also referred as “TSG CUT”), which divides the top select gate (TSG) into multiple top select lines. The select gate isolation structures may also be a bottom select gate isolation structures (also referred as “BSG CUT”), which divides the bottom select gate (BSG) into multiple bottom select lines. The gate isolation structures may include first gate isolation structures 323 and second gate isolation structures 327. The first gate isolation structures 323 can divide the memory array into multiple blocks 388, while multiple second gate isolation structures 327 can further divide each block 388 into multiple finger regions (i.e., Fingers) 355. A select gate isolation structures 331 positioned in the middle of each finger region 355 can divide the finger region 355 into two parts, thereby splitting the finger region 355 into two memory slices 344. As shown in FIG. 3, one block contains six memory slices; however, in practical applications, the number of memory slices in a block is not limited to this. FIG. 3 exemplarily illustrates only one block of the memory, but the memory includes multiple blocks as shown in FIG. 3, with adjacent blocks separated by the first gate isolation structure, and multiple blocks may be arranged along the Y direction.

It should be noted that the number of rows of memory cells between the gate isolation structures and select gate isolation structures shown in FIG. 3 is merely an example and is not intended to limit the number of rows of memory cells included in a finger region of a three-dimensional NAND memory in the present disclosure. In practical applications, the number of rows of memory cells included in a finger region can be adjusted based on specific circumstances, such as 2, 4, 8, 16, etc.

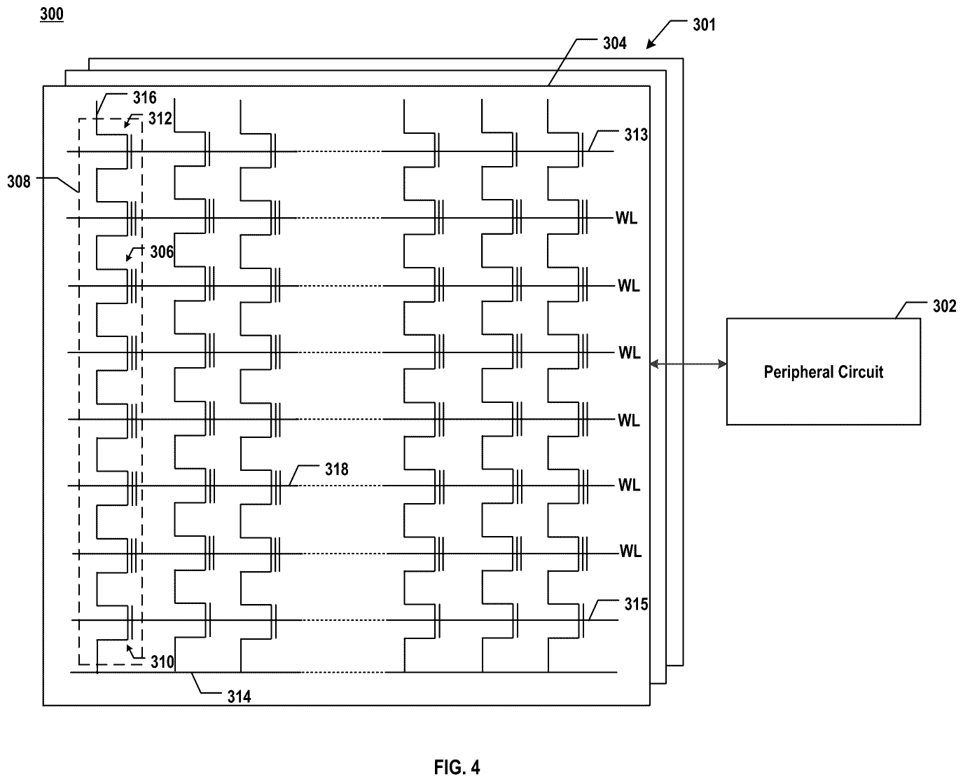

FIG. 4 is a schematic diagram of an exemplary second semiconductor structure including peripheral circuit, according to implementations of the present disclosure. The second semiconductor structure 300 may include a memory array 301 and peripheral circuit 302 coupled to the memory array 301. The memory array 301 is described using a three-dimensional NAND memory array as an example, wherein the memory cells 306 are NAND memory cells provided in the form of an array of memory strings 308, with each memory string 308 extending vertically. In some implementations, each memory string 308 includes multiple memory cells 306 that are serially coupled and vertically stacked. Each memory cell 306 can hold a continuous analog value, such as voltage or charge, depending on the number of electrons captured within the region of the memory cell 306. Each memory cell 306 may be a floating gate type memory cell including a floating gate transistor, or a charge trap type memory cell including a charge trap transistor.

In some implementations, each memory cell 306 is a single-level cell (SLC) with two possible memory states, thereby capable of storing one bit of data. For example, the first memory state “0” may correspond to a first voltage range, and the second memory state “1” may correspond to a second voltage range. In some implementations, each memory cell 306 is a multi-level cell capable of storing more than one bit of data across four or more memory states, such as a multi-level cell (MLC) storing two bits per cell, a triple-level cell (TLC) storing three bits per cell, or a quad-level cell (QLC) storing four bits per cell.

As shown in FIG. 4, each memory string 308 may include a bottom select transistor (also referred as bottom Select gate, BSG) 310 at its source end and a top select transistor (also referred as top select gate, TSG) 312 at its drain end. The bottom select transistor 310 and the top select transistor 312 may be configured to activate a selected memory string 308 during read and program operations. In some implementations, the source ends of the memory strings 308 within the same block 304 may be coupled through a common source line (CSL) 314. In other words, all memory strings 308 in the same block 304 share a common source (also referred as array common source, ACS). According to some implementations, the top select transistor 312 of each memory string 308 is coupled to a corresponding bit line 316, through which data can be read from or written to via an output bus (not shown). In some implementations, each memory string 308 is configured to be selected or deselected by applying a select voltage (e.g., a voltage above the threshold voltage of the top select transistor 312) or a deselect voltage (e.g., 0V) to the corresponding top select transistor 312 via one or more top select lines (TSL) 313, and/or by applying a select voltage (e.g., a voltage above the threshold voltage of the bottom select transistor 310) or a deselect voltage (e.g., 0V) to the corresponding bottom select transistor 310 via one or more bottom select lines (BSL) 315.

As shown in FIG. 4, the memory strings 308 may be organized into multiple blocks 304, each of which may have a common source line 314. In some implementations, each block 304 is the basic data unit for erase operations, meaning all memory cells 306 within the same block 304 are erased simultaneously. To erase the memory cells 306 in a selected block, an erase voltage may be applied to bias the common source line 314 coupled to the selected block as well as unselected blocks on the same plane as the selected block. It should be understood that, in some examples, erase operations may be performed at a half-block level, a quarter-block level, or any suitable level with any appropriate number of blocks or fraction of blocks. The memory cells 306 of adjacent memory strings 308 may be coupled through word lines 318, which determine which row of memory cells 306 is affected by read and program operations.

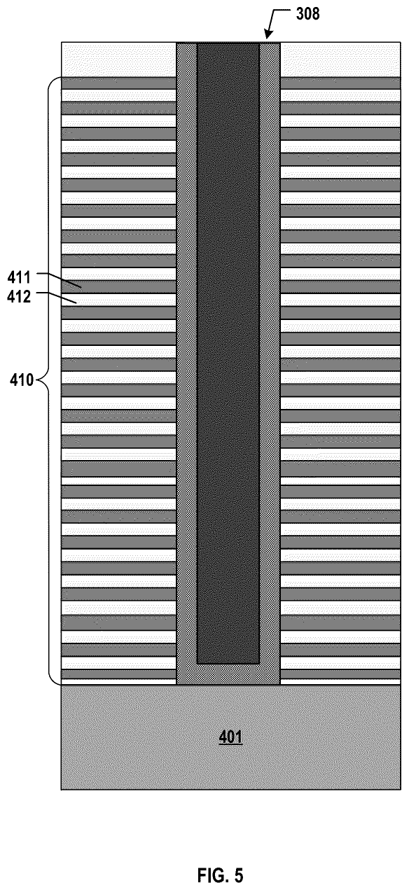

FIG. 5 illustrates a cross-sectional schematic diagram of an exemplary memory array including memory strings 308, according to some aspects of the present disclosure. As shown in FIG. 5, the stacked structure 410 includes multiple gate layers 411 and multiple insulating layers 412 alternately stacked in sequence, along with memory strings 308 vertically extending through through the gate layers 411 and insulating layers 412. The gate layers 411 and insulating layers 412 may be alternately stacked, with adjacent gate layers 411 separated by an insulating layer 412. The number of memory cells included in the memory array is primarily related to the number of pairs of gate layers 411 and insulating layers 412 in the stacked structure 410.

The constituent material of the gate layers 411 may include conductive materials. Conductive materials include, but are not limited to, tungsten (W), cobalt (Co), copper (Cu), aluminum (Al), polysilicon, doped silicon, silicides, or any combination thereof. In some implementations, each gate layer 411 includes a metal layer, such as a tungsten layer. In some implementations, each gate layer 411 includes a doped polysilicon layer. Each gate layer 411 may include a control gate surrounding the memory cells. The gate layer 411 at the top of the stacked structure 410 may extend laterally as a top select line, the gate layer 411 at the bottom of the stacked structure 410 may extend laterally as a bottom select line, and the gate layers 411 extending laterally between the top select line and the bottom select line may serve as word line layers.

In some implementations, the stacked structure 410 may be disposed on a semiconductor layer 401. The semiconductor layer 401 may include silicon (e.g., single-crystal silicon), silicon-germanium (SiGe), gallium arsenide (GaAs), germanium (Ge), silicon-on-insulator (SOI), germanium-on-insulator (GOI), or any other suitable material. In other implementations, the semiconductor device may not include this semiconductor layer.

In some implementations, the memory string 308 includes a channel structure extending vertically through the stacked structure 410. In some implementations, the channel structure includes a channel hole filled with one or more semiconductor materials (e.g., as a semiconductor channel) and one or more dielectric materials (e.g., as a memory film). In some implementations, the semiconductor channel includes silicon, such as polysilicon. In some implementations, the memory film is a composite dielectric layer including a tunneling layer, a storage layer (also referred to as a “charge trapping/storage layer”), and a blocking layer. The channel structure may have a cylindrical shape (e.g., a pillar shape). According to some implementations, the semiconductor channel, tunneling layer, storage layer, and blocking layer are radially arranged in that order from the center of the pillar toward its outer surface. The tunneling layer may include silicon oxide, silicon oxynitride, or any combination thereof. The storage layer may include silicon nitride, silicon oxynitride, or any combination thereof. The blocking layer may include silicon oxide, silicon oxynitride, high-k dielectric materials, or any combination thereof. In one example, the memory film may include a composite layer of silicon oxide/silicon oxynitride/silicon oxide (ONO).

Referring back to FIG. 4, the peripheral circuit 302 may be coupled to the memory array 301 through bit lines 316, word lines 318, source lines 314, bottom select lines (BSL) 315, and top select lines (TSL) 313. The peripheral circuit 302 may include any suitable analog, digital, and mixed-signal circuits to facilitate the operation of the memory array 301 by applying voltage signals and/or current signals to each target memory cell 306 and sensing voltage signals and/or current signals from each target memory cell 306 via the bit lines 316, word lines 318, source lines 314, BSL 315, and TSL 313. The peripheral circuit 302 may include various types of peripheral circuits formed using metal-oxide-semiconductor technology.

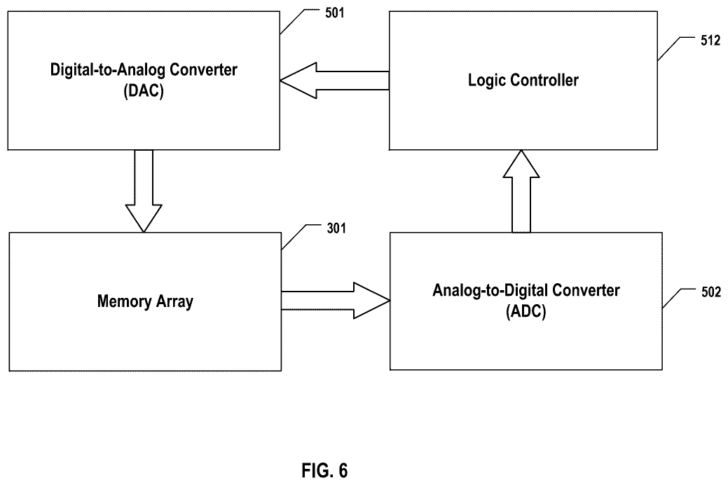

FIG. 6 is a first schematic diagram of a second semiconductor structure including peripheral circuit and a memory array, according to implementations of the present disclosure. Referring to FIG. 4 and FIG. 6 together, the peripheral circuit 302 may include control logic 512, a digital-to-analog converter (DAC) 501 coupled to the control logic 512 and the memory array 301, and an analog-to-digital converter (ADC) 502 coupled to the memory array 301 and the control logic 512. When performing a first operation using the second semiconductor structure, the digital-to-analog converter (DAC) 501 can convert digital signals into the voltage signals required by the memory array 301 in the second semiconductor structure. The analog-to-digital converter 502 can convert current signals output by the memory array 301 into digital signals. The control logic 512 may be coupled to the peripheral circuit and configured to control the operation of the peripheral circuit. The control logic 512 may also be used to receive input data sent by an external device. In some implementations, the digital-to-analog converter (DAC) 501 is a one-bit DAC, and the analog-to-digital converter 502 is a one-bit ADC.

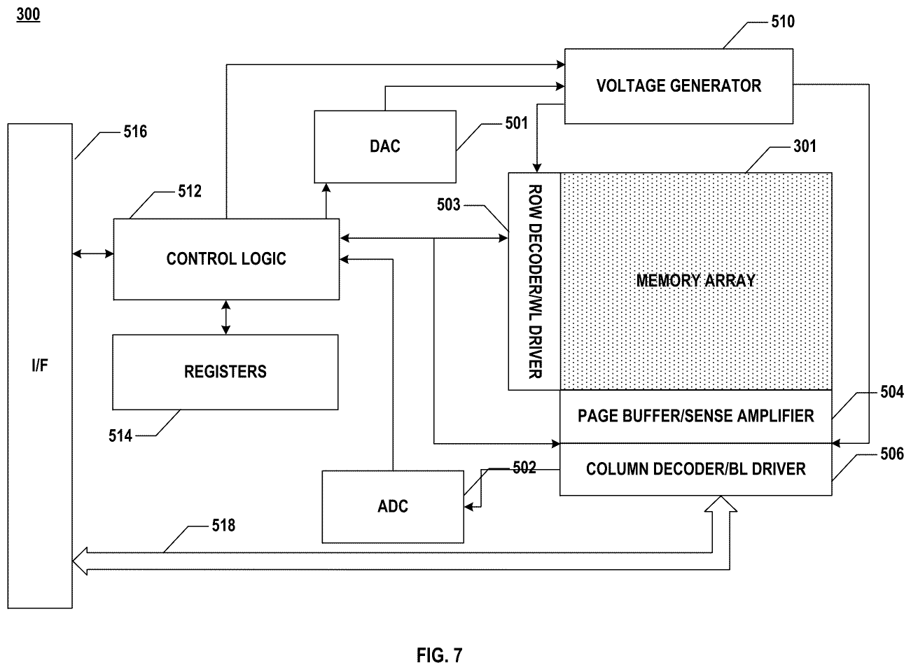

FIG. 7 is a second schematic diagram of the composition of an exemplary second semiconductor structure including a memory array and peripheral circuit, according to implementations of the present disclosure. In addition to the circuit structure shown in FIG. 6, the peripheral circuit 302 may further include a page buffer/sense amplifier 504, a column decoder/bit line driver 506, a row decoder/word line driver 508, a voltage generator 510, registers 514, and a data bus 518. It should be understood that, in some examples, additional peripheral circuit not shown in FIG. 6 or FIG. 7 may also be included.

The control logic 512 may be coupled to each of the peripheral circuits described above and configured to control the operation of each peripheral circuit. The registers 514 may be coupled to the control logic 512 and include a status register, a command register, and an address register, used to store status information, command operation codes (OP codes), and command addresses for controlling the operation of each peripheral circuit.

The page buffer/sense amplifier 504 may be configured to read data from the memory array 301 and program (write) data to the memory array 301 based on control signals from the control logic 512. In one example, the page buffer/sense amplifier 504 may store programming data (write data) to be programmed into the memory cells 306 of the memory array 301. In another example, the page buffer/sense amplifier 504 may perform a program verification operation to ensure that the data has been correctly programmed into the memory cells 306 coupled to a selected word line 318. The column decoder/bit line driver 506 may be configured to be controlled by the control logic 512 and select one or more NAND memory strings 308 by applying bit line voltages generated by the voltage generator 510.

The row decoder/word line driver 508 may be configured to be controlled by the control logic 512, selecting/deselecting blocks 304 of the memory array 301 and selecting/deselecting word lines 318 within the blocks 304. The row decoder/word line driver 508 may also be configured to drive the word lines 318 using word line voltages generated by the voltage generator 510. In some implementations, the row decoder/word line driver 508 may also select/deselect and drive the bottom select lines (BSL) 315 and top select lines (TSL) 313. As described in detail below, the row decoder/word line driver 508 is configured to perform programming operations on the memory cells 306 coupled to one or more selected word lines 318. The voltage generator 510 may be configured to be controlled by the control logic 512 and generate word line voltages (e.g., read voltage, program voltage, pass voltage, local voltage, verification voltage, etc., input voltage), bit line voltages, and source line voltages to be supplied to the memory array 301.

Referring back to FIG. 1, in implementations of the present disclosure, the first sub-semiconductor structure includes a first bonding layer 101 and a second bonding layer 102. The memory array 301 is bonded to the second sub-semiconductor structure through the first bonding layer 101, and the memory array 301 is bonded to the first semiconductor structure 200 through the second bonding layer 102. In some implementations, the first semiconductor structure 200 and the second semiconductor structure 300 may be vertically connected through bonding. This bonding connection includes hybrid bonding (also referred to as “metal/dielectric hybrid bonding”), which is a direct bonding technique—for example, forming a bond between surfaces without using an intermediate layer such as solder or adhesive—and can simultaneously achieve metal-to-metal bonding and dielectric-to-dielectric bonding. It should be noted that the term “bonding” as used in the present disclosure may refer to any suitable bonding technique, such as the aforementioned hybrid bonding, anodic bonding, fusion bonding, transfer bonding, adhesive bonding, eutectic bonding, and the like.

In some implementations of the present disclosure, the memory array 301 is located between the first bonding layer 101 and the second bonding layer 102; the second sub-semiconductor structure includes a third bonding layer 103, which is bonded to the first bonding layer 101; the first semiconductor structure 200 includes a fourth bonding layer 104, which is bonded to the second bonding layer 102.

In some implementations, the first semiconductor structure 200 and the peripheral circuit 302 are respectively located on opposite sides of the memory array 301. In other words, the memory array 301 is vertically positioned between the first semiconductor structure 200 and the peripheral circuit 302.

In some implementations, the semiconductor device may further include a first bonding interface between the third bonding layer 103 and the first bonding layer 101, and a second bonding interface between the fourth bonding layer 104 and the second bonding layer 102. Data transfer between the first sub-semiconductor structure and the second sub-semiconductor structure can be achieved through interconnects (e.g., bonding contacts) spanning the first bonding interface. Data transfer between the first semiconductor structure and the second semiconductor structure can be achieved through interconnects (e.g., bonding contacts) spanning the second bonding interface.

In some implementations, a first interconnect layer (not shown in the figure) may also be included between the memory array 301 and the first bonding layer 101, and a second interconnect layer (not shown in the figure) may also be included between the peripheral circuit 302 and the third bonding layer 103. The first interconnect layer and the second interconnect layer may include multiple interconnect structures, such as lateral lines and vias, which may be formed within one or more interlayer dielectric (ILD) layers. The interconnect structures may include conductive materials, including but not limited to tungsten (W), cobalt (Co), copper (Cu), aluminum (Al), silicides, or any combination thereof. The ILD layers in the interconnect layers may include dielectric materials, including but not limited to silicon oxide, silicon nitride, silicon oxynitride, low-k dielectrics, or any combination thereof.

In some implementations of the present disclosure, the first bonding layer 101 includes first bonding contacts and a first dielectric layer that isolates the first bonding contacts, and the third bonding layer 103 includes third bonding contacts and a third dielectric layer that isolates the third bonding contacts; the first bonding contacts are bonded to the third bonding contacts, and the first dielectric layer is bonded to the third dielectric layer.

In some implementations of the present disclosure, the second bonding layer 102 includes second bonding contacts and a second dielectric layer that isolates the second bonding contacts; the fourth bonding layer 104 includes fourth bonding contacts and a fourth dielectric layer that isolates the fourth bonding contacts; the second bonding contacts are bonded to the fourth bonding contacts, and the second dielectric layer is bonded to the fourth dielectric layer.

In some implementations, the bonding contacts may include conductive materials, including but not limited to tungsten (W), cobalt (Co), copper (Cu), aluminum (Al), silicides, or any combination thereof. In a specific example, the bonding contacts of the bonding layer include Cu. The remaining area of the bonding layer may be formed of a dielectric, including but not limited to silicon oxide, silicon nitride, silicon oxynitride, low-k dielectrics, or any combination thereof. The bonding contacts and surrounding dielectric in the bonding layer may be used for hybrid bonding, enabling simultaneous metal-to-metal bonding and dielectric-to-dielectric bonding.

In some implementations of the present disclosure, the analog-to-digital converter (ADC) circuit is connected to the memory array 301 through the fourth bonding layer 104 and the second bonding layer 102, and receives the analog computation information output by the memory array 301 after performing the first operation via the fourth bonding layer 104 and the second bonding layer 102.

Referring to FIG. 1, FIG. 6, and FIG. 7 together, when performing the first operation using the second semiconductor structure, the control logic 512 may receive input data sent by an external device (e.g., a host). The digital-to-analog converter (DAC) 501 in the peripheral circuit 302 converts the input data into voltage signals required to be applied to the word lines or bit lines. The voltage generator 510 generates the corresponding voltages needed for the word lines or bit lines. The row decoder/word line driver 508 is configured to drive the selected word lines using the word line voltages generated by the voltage generator 510, or the column decoder/bit line driver 506 is configured to drive the selected bit lines using the bit line voltages generated by the voltage generator 510. The analog computation information obtained after performing the first operation is transmitted to the analog-to-digital converter (ADC) circuit through the fourth bonding layer 104 and the second bonding layer 102. The analog-to-digital converter (ADC) circuit converts the analog computation information into digital information, which is then transmitted to the data processing circuit. Finally, the data processing circuit performs a second operation on the digital information.

In some implementations, for a computing-in-memory (CIM) chip, it is necessary to perform a first operation between input data and a weight matrix. The input data may be an input vector or input matrix composed of multiple elements, and the weight matrix is composed of multiple weights. Each element in the input data needs to undergo a multiply-accumulate operation with multiple weights in the weight matrix to obtain the corresponding element in the output data.

To achieve the above computational function, the memory array 301 may be configured to store the weight matrix. Specifically, the weights in the weight matrix can be written into the memory array 301 according to a certain mapping rule, with each memory cell 306 in the memory array 301 configured to store one weight. During the computation phase, the second semiconductor structure may receive input data from an external device. The input data, which may be an input vector or input matrix composed of multiple elements, can have each element converted into an input voltage by the digital-to-analog converter (DAC) 501 and input into the memory array 301 via bit lines 316 or word lines 318.

In some implementations of the present disclosure, the analog computation information may be output via the bit lines or via the source end. In other words, in the second semiconductor structure, the bit lines serve as the analog information output end, or the source end serves as the analog information output end.

In some implementations of the present disclosure, by placing the analog-to-digital converter (ADC) circuit in the first semiconductor structure, when the source end is the analog information output end, the voltage/current signals output from the source end are transmitted through the hybrid bonding channel (second bonding layer and fourth bonding layer) to the analog-to-digital converter (ADC) circuit for analog-to-digital conversion. This approach eliminates the need for a digitization process (analog-to-digital conversion) of the analog computation information within the peripheral circuit, and consequently, there is no need for a compression module to compress the digitized results. This significantly reduces the frequency requirements for interface data transmission.

The following description takes the bit line as the analog signal output end as an example to provide an illustrative explanation of the specific process of the first operation.

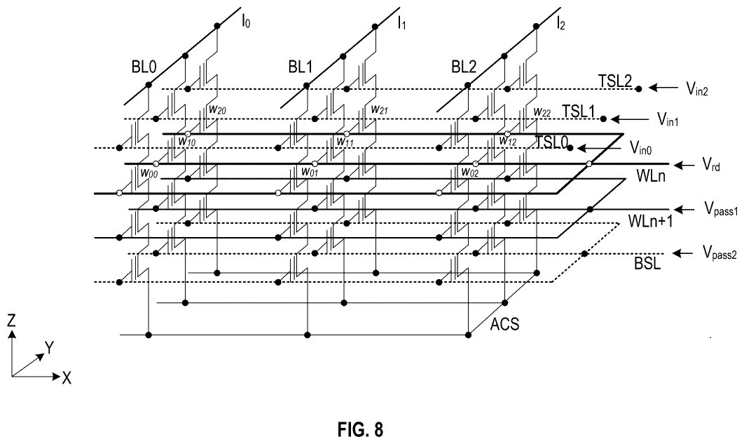

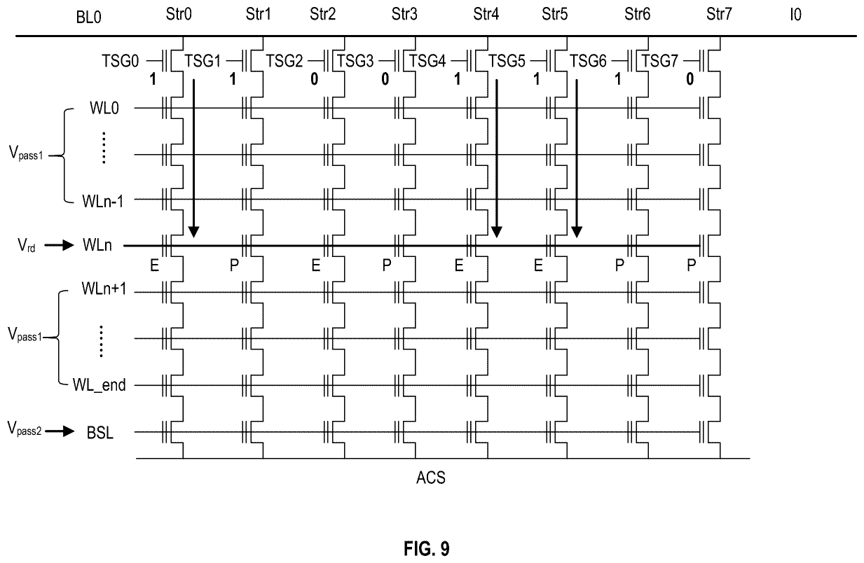

FIG. 8 is a schematic diagram illustrating the input of voltage to a block via top select lines, according to some implementations of the present disclosure. FIG. 9 is a schematic diagram illustrating multiple memory strings coupled to a single bit line, according to some implementations of the present disclosure. It should be noted that the number of bit lines, the number of memory strings coupled to each bit line, and the number of memory cells in each memory string shown in FIG. 8 and FIG. 9 are merely examples, and the present disclosure does not impose restrictions on the specific quantities of these structures.

As shown in FIG. 8, input voltages corresponding to elements in the input data may be input through multiple top select lines. During the phase of performing the first operation using the memory array, the peripheral circuit is configured to: apply a first read voltage Vrd to the target word line WLn coupled to the target block; apply corresponding input voltages to the multiple top select lines coupled to the target block—for example, input voltages Vin0, Vin1, and Vin2 may be applied to the top select lines TSL0, TSL1, and TSL2, respectively; apply a first pass voltage to non-target word lines coupled to the target block—for example, a first pass voltage Vpass1 may be applied to word line WLn+1; and apply a second pass voltage to the bottom select line coupled to the target block—for example, a second pass voltage Vpass2 may be applied to the bottom select line BSL. The analog computation information can be obtained by sensing the current on the bit lines coupled to the target block. For instance, by sensing the current I0 on bit line BL0 and converting it, the sum of the following products can be obtained: the product of the element corresponding to input voltage Vin0 and weight w00, the product of the element corresponding to input voltage Vin1 and weight w10, and the product of the element corresponding to input voltage Vin2 and weight w20. In some implementations, the first operation includes a multiply-accumulate operation.

In some implementations, the peripheral circuit is configured to: before performing the first operation using the memory array, apply corresponding programming voltages to the target word line coupled to the target block to program the memory cells coupled to the target word line.

In a specific example, the memory cells in the target block are configured to store one bit of data, with the multiple memory cells in the target block having a first memory state and a second memory state. The threshold voltage of memory cells in the first memory state is lower than that of memory cells in the second memory state. The first read voltage Vrd is greater than the threshold voltage of memory cells in the first memory state but less than the threshold voltage of memory cells in the second memory state. Here, the memory cells in the target block may be single-level cells (SLCs) storing one bit of data, where the first memory state may be the erased state (E) and the second memory state may be the programmed state (P). The peripheral circuit may be configured to perform a programming operation on the memory cells coupled to the target word line before the first operation, writing weights into the memory cells according to a certain mapping rule. For single-level cells, the process of writing weights involves applying corresponding programming voltages to adjust the threshold voltages of some memory cells coupled to the target word line to fall within the threshold voltage distribution range corresponding to the second memory state.

In some implementations, as shown in FIG. 9, taking as an example a target block that includes eight memory strings coupled to bit line BL0, among the memory cells coupled to the target word line WLn, four memory cells are in the first memory state (i.e., erased state E), and the other four are in the second memory state (i.e., programmed state P). Input data can be input through eight top select lines TSL0 to TSL7. Specifically, the input data may be an input vector consisting of eight elements, which may include five “1” and three “0”. The digital-to-analog converter (DAC) circuit can convert each element of the input vector into a corresponding voltage signal, and the voltage generator converts these voltage signals into input voltages required to be applied to the top select lines. These input voltages are then transmitted to the top select lines via drivers coupled to the top select lines. Specifically, eight input voltages can be simultaneously applied to the eight top select lines. The input voltages corresponding to “1” including Vin0, Vin1, Vin4, Vin5, and Vin6—can turn on the top select transistors TSG0, TSG1, TSG4, TSG5, and TSG6 coupled to top select lines TSL0, TSL1, TSL4, TSL5, and TSL6, respectively. The input voltages corresponding to “0” including Vin2, Vin3, and Vin7—can turn off the top select transistors TSG2, TSG3, and TSG7 coupled to top select lines TSL2, TSL3, and TSL7, respectively.

In a specific example, as shown in FIG. 9, the current I0 on bit line BL0 is the sum of the output currents from the eight memory strings coupled to bit line BL0. The input voltages on the top select lines coupled to memory strings Str0, Str4, and Str5 cause the top select transistors TSG0, TSG4, and TSG5 to be in the on state, and the memory cells in memory strings Str0, Str4, and Str5 coupled to the target word line WLn are in the first memory state (i.e., erased state E). Consequently, memory strings Str0, Str4, and Str5 are conductive, producing a current greater than or equal to a preset current. The current I0 on bit line BL0 is substantially equal to the sum of the output currents from memory strings Str0, Str4, and Str5, and the multiple of current I0 relative to the current produced by any single memory string among Str0, Str4, and Str5 is approximately 3. If the weight value stored in a memory cell in the first memory state is equivalently set to “1” and the weight value stored in a memory cell in the second memory state is equivalently set to “0,” then the operation performed by the eight memory strings coupled to bit line BL0 can be equivalently expressed as: 1×1+1×0+0×1+0×0+1×1+1×1+1×0+0×0=3.

Based on the specific example above, when the target block includes Y+1 memory strings coupled to bit line BLx, the Y+1 elements corresponding to the input voltages input via Y+1 first select lines are α0, α1, . . . , αY, and the weights stored in the Y+1 memory cells coupled to the target word line WLn are w0, w1, . . . , wY. The analog computation information, equivalent to the multiple of the current on bit line BLx relative to an output current greater than or equal to a preset current, can be expressed as α0×w0+α1×w1+ . . . +αY×wY.

In implementations of the present disclosure, when it is necessary to perform the first operation using multiple banks, the first pass voltage can be simultaneously applied to the non-target word lines in multiple banks. As a result, the voltage setup phases for the first pass voltage applied to the non-selected word lines coupled to different banks can overlap. Compared to the approach of applying the first pass voltage to non-selected word lines coupled to different banks in separate computation phases, this method can shorten the overall computation time and improve the computational efficiency of performing the first operation using multiple banks.

Furthermore, for each bank, multiple blocks within that bank can be used simultaneously to perform the first operation. The peripheral circuit can be configured to: apply a first read voltage to the target word lines respectively coupled to the multiple blocks of the bank; apply corresponding input voltages to the multiple first select lines respectively coupled to the multiple blocks of the bank; and sense the currents on the bit lines coupled to the multiple blocks of the bank. Specifically, the first read voltage Vrd can be simultaneously applied to the target word lines respectively coupled to multiple blocks Block0 to BlockN in bank Bank0, while corresponding input voltages Vin are simultaneously applied to the multiple first select lines respectively coupled to the multiple blocks Block0 to BlockN. The currents on the bit lines coupled to the multiple blocks Block0 to BlockN are then sensed, where the current on each bit line represents the analog computation information resulting from the first operation performed by all memory strings coupled to that bit line. Thus, multiple blocks can perform the first operation in parallel, further enhancing the computational efficiency and processing power of the semiconductor device.

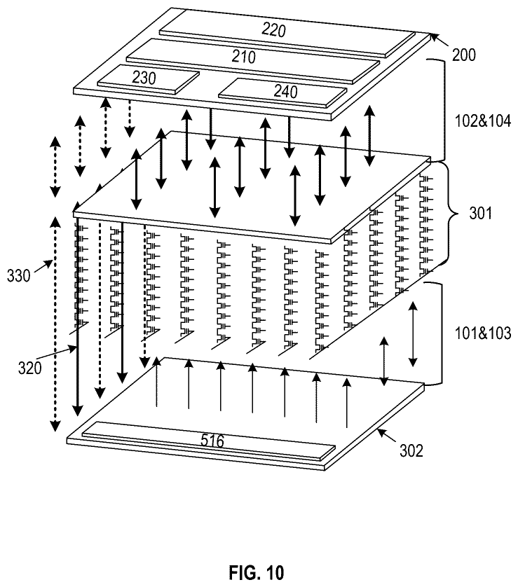

FIG. 10 is a second structural diagram of a semiconductor device according to one exemplary implementation of the present disclosure. Referring to FIG. 10, the first semiconductor structure 200 includes an analog-to-digital converter circuit 210 and a data processing circuit 220. It should be noted that FIG. 10 uses the bit line as the analog signal output end as an example for illustration.

In implementations of the present disclosure, the second semiconductor structure 300 further includes first interconnect structures 320 that extends through the memory array 301 and connects to the bit line and the second bonding layer. The memory array 301 is connected to the analog-to-digital converter circuit 210 through the bit line, the first interconnect structures 320, the second bonding layer, and the fourth bonding layer. In a specific example, the first interconnect structures 320 can be through-array contacts (TAC). In some implementations, one end of each first interconnect structure 320 can be connected to a bit line, and the other end is connected to the second bonding layer. Thus, the bit line can be connected to the analog-to-digital converter circuit 210 via the first interconnect structures 320, the second bonding layer, and the fourth bonding layer, thereby transmitting the analog computation information to the analog-to-digital converter circuit 210.

In implementations of the present disclosure, the first semiconductor structure 200 further includes a first interface circuit 230 and a controller 240. The first interface circuit 230 is configured to receive and send data between the semiconductor device and other external devices. Specifically, the first interface circuit 230 is configured to output the computation results of the second operation performed by the data processing circuit 220 to external devices. The controller 240 may be configured to control the operations of the first semiconductor structure 200 and the second semiconductor structure 300. In other words, the controller 240 can serve as both a memory controller managing data storage and transmission in the second semiconductor structure 300 and a computation controller managing data computation and transmission in the first semiconductor structure 200. In some implementations, the controller 240 is also configured to control data transmission between the first semiconductor structure 200 and the second semiconductor structure 300. In some implementations, the controller 240 is further configured to receive input data sent by an external device and transmit the input data to the second semiconductor structure 300.

In some implementations, the controller 240 is coupled to the second semiconductor structure 300 and an external device (e.g., a host) and is configured to control the second semiconductor structure 300. The controller 240 can manage the data stored in the second semiconductor structure 300 and communicate with the external device.

In some implementations, the controller 240 may also be configured to manage various functions related to data stored in or to be stored in the second semiconductor structure 300, including but not limited to bad block management, garbage collection, logical-to-physical address translation, and wear leveling. In some implementations, the controller 240 is further configured to process error correction codes (ECC) for data read from or written to the second semiconductor structure. In some implementations, the controller 240 may also perform any other suitable functions, such as formatting the second semiconductor structure.

In some implementations, the first interface circuit 230 may be configured within the controller 240, and interface protocols may be used as the first interface circuit between the controller 240 and external devices. Thus, the controller 240 can communicate with external devices through at least one of various interface protocols, such as USB protocol, MMC protocol, Peripheral Component Interconnect (PCI) protocol, PCI Express (PCI-E) protocol, Advanced Technology Attachment (ATA) protocol, Serial ATA protocol, Parallel ATA protocol, Small Computer System Interface (SCSI) protocol, Enhanced Small Disk Interface (ESDI) protocol, Integrated Drive Electronics (IDE) protocol, Firewire protocol, etc. Here, the first interface circuit 230 may also be referred to as a front-end interface. In some implementations, the controller 240 interacts with the second semiconductor structure 300 for commands/data through multiple configured channels. These channels are also referred to as back-end interfaces.

In some implementations of the present disclosure, the second semiconductor structure 300 further includes fourth interconnect structures 330 extending through the memory array 301. One end of each fourth interconnect structure 330 is connected to the second sub-semiconductor structure, and the other end is connected to the first interface circuit 230 through the fourth bonding layer 104 and the second bonding layer 102. Thus, the peripheral circuit 302 in the second semiconductor structure can be connected to the first interface circuit 230 via the fourth interconnect structures 330 and perform data transmission with other external devices through the first interface circuit 230.

It should be noted that the dashed arrows in FIG. 10 represent the fourth interconnect structures 330, and the number of these dashed arrows is merely an example and not intended to limit the present disclosure. It should also be noted that the bonding layers between the first semiconductor structure 200 and the memory array 301 (i.e., the second bonding layer 102 and the fourth bonding layer 104) may further include additional interconnect structures coupled to the fourth interconnect structures 330, enabling the fourth interconnect structures 330 to be connected to the first interface circuit 230 through the second bonding layer 102 and the fourth bonding layer 104.

In some implementations of the present disclosure, referring to FIG. 7 and FIG. 10, the second semiconductor structure further includes a second interface circuit 516. Specifically, the second sub-semiconductor structure includes the second interface circuit 516, and the second semiconductor structure is also connected to the first semiconductor structure via the second interface circuit. That is, the second interface circuit 516 here is the interface coupled to the back-end interface of the aforementioned controller; in other words, the second interface circuit 516 can also serve as the communication interface between the second semiconductor structure and the first semiconductor structure. The second interface circuit 516 may be coupled to the control logic 512 and act as a control buffer, buffering control commands received from a host (not shown) and relaying them to the control logic 512, as well as buffering status information received from the control logic 512 and relaying it to the host. The second interface circuit 516 may also be coupled to the column decoder/bit line driver 506 via the data bus 518, serving as a data I/O interface and data buffer to buffer data and relay it to the memory array 301 or relay/buffer data from the memory array 301.

In some implementations, the data processing circuit 220 in the first semiconductor structure 200 includes a processor, which may be a specialized processor, including but not limited to a CPU, GPU, digital signal processor (DSP), tensor processing unit (TPU), vision processing unit (VPU), neural processing unit (NPU), synergistic processing unit (SPU), physical processing unit (PPU), and image signal processor (ISP). In a specific example, the data processing circuit is an NPU. The NPU can perform operations such as arithmetic/logical operations, rotation and shift operations, compensation operations, activation operations, and pooling operations.

In some implementations of the present disclosure, the second operation includes one or more of compensation, activation, shift, or pooling operations. In a specific example, the second semiconductor structure in the semiconductor device is configured to store a weight matrix, perform a multiply-accumulate operation, and output analog computation information; the first semiconductor structure in the semiconductor device is configured to convert the analog computation information output by the second semiconductor structure into digital information and perform an activation operation on the digital information to generate an output result. In some implementations, the activation operation can be implemented through activation functions stored in the NPU, which may include but are not limited to step functions, rectification functions, sigmoid functions, hyperbolic tangent (tanh) functions, and softplus functions (also known as smooth rectification).

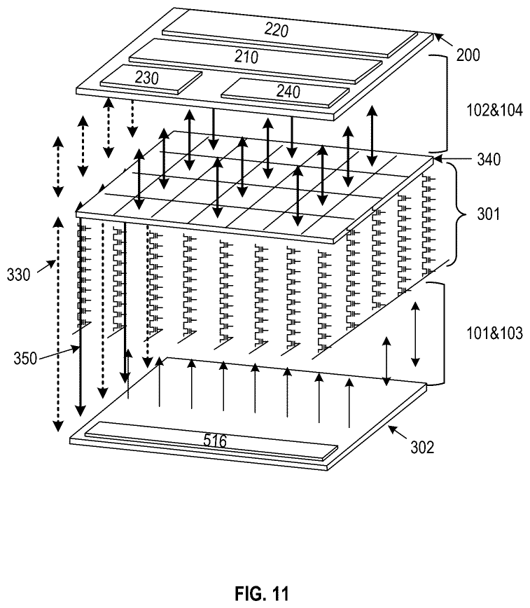

FIG. 11 is a third structural diagram of a semiconductor device according to one exemplary implementation of the present disclosure. It should be noted that FIG. 11 uses the source end as the analog signal output end as an example for illustration.

Referring to FIG. 11, the source end is connected to the analog-to-digital converter circuit 210 through the second bonding layer and the fourth bonding layer. Thus, when the source end serves as the analog information output end of the memory array 301, the analog computation information can be transmitted to the analog-to-digital converter circuit 210 via the second bonding layer 102 and the fourth bonding layer 104.

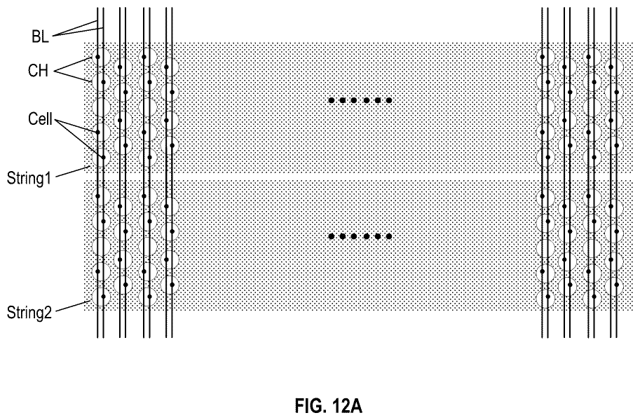

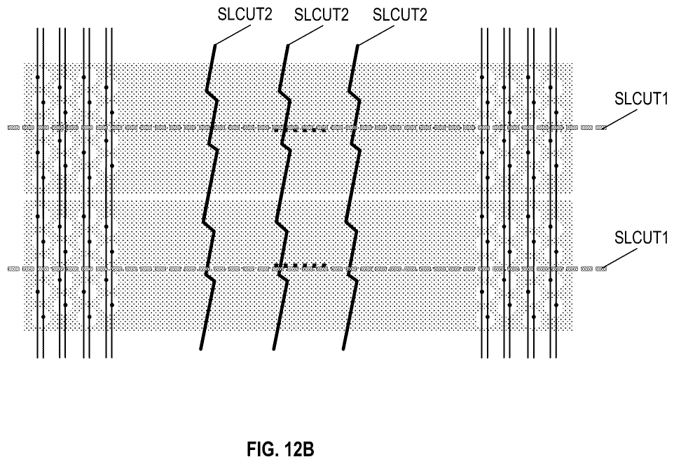

FIG. 12A is a first top-down schematic view of a first sub-semiconductor structure including a memory array, according to one exemplary implementation of the present disclosure. Referring to FIG. 12A, the gate isolation structures (GLS) and top select gate isolation structures (TSG CUT) divide the block into multiple memory slices (Strings), such as six (FIG. 12A shows two Strings, namely String1 and String2), with different Strings coupled to different top select gates (TSGs). As shown in FIG. 12A, the bit line BL is coupled to the channel structure CH, wherein, in a column of channel structures along the bit line extension direction, the memory cells of adjacent channel structures are coupled to different bit lines BL. The source layer (not shown in FIG. 12A) is interconnected on a per-block basis. It can be understood that when the source layer (common source) is not segmented, regardless of the amount or type of data input, the entire block will be occupied due to the interconnection of the source layer, and the bit lines BL and memory cells not used for data input will be wasted. In other words, due to the interconnection of the source layer, parallelism is extremely low, resulting in significant waste, especially for small-scale weight data.

In some implementations of the present disclosure, the first sub-semiconductor structure further includes a source layer 340, with the source end connected to the source layer 340. The source layer 340 is located on the side of the memory array 301 near the second bonding layer 102. The source layer 340 includes first isolation structures each extending along the word line direction and a second isolation structures extending along the bit line direction, with the first and second isolation structures dividing the source layer into multiple sub-source regions. The source layer may include one or more layers. For example, the source layer may include a conductive layer and a semiconductor layer. In some examples, the material of the source layer is a semiconductor material, including but not limited to intrinsic polysilicon, doped polysilicon (e.g., N-type doped silicon, P-type doped silicon), etc. In some implementations, the source layer may be used to form a common source. That is, multiple memory strings within the same block are coupled together.

It is noted that, in the above and following descriptions, the first direction can be the same as the direction in which the bit line extends; the second direction can be perpendicular to the bit line extension direction and parallel to the word line extension direction; the third direction can be perpendicular to both the first and second directions, and the extension direction of the memory strings may be parallel to the third direction.

FIG. 12B is a second top-down schematic view of a first sub-semiconductor structure including a memory array, according to one exemplary implementation of the present disclosure. Referring to FIG. 12B, the source layer includes multiple first sub-source regions spaced along the first direction and multiple second sub-source regions spaced along the second direction. The source layer is divided into multiple first sub-source regions by first isolation structures SLCUT1 extending along the second direction. The first isolation structures may extend through the source layer along the third direction. The source layer is also divided into multiple second sub-source regions by a second isolation structures SLCUT2 extending along the first direction. The second isolation structures may extend through the source layer along the third direction.

In some implementations, during the first operation phase, before the first operation begins, weight data is written into the corresponding memory cells of the memory array according to a certain mapping rule. The M memory cells storing the same weight data are located in M memory strings, each coupled to a different first sub-source region, where M is an integer greater than 1. In other words, in implementations of the present disclosure, at least two memory cells are used together to store the same weight data. Different memory cells among these at least two memory cells are used to store different data bits of the same weight data. This allows the bit width of the weight data to not be limited by the storage bit capacity of a single memory cell, enabling the present disclosure to support the storage of weight data with more bits, thereby enhancing parallelism.

It can be understood that, in some implementations, the source layer is segmented into multiple first sub-source regions. This separation of multiple first sub-source regions facilitates performing different subsequent operations on the output data from different first sub-source regions, such as applying different shift operations and then summing the shifted data. The separation of multiple first sub-source regions enables different memory cells among the M memory cells storing the same weight data to store different data bits of that weight data.

In some implementations, M can be determined based on the data type of the weight data and the storage bit capacity of the memory cells. For example, if the weight data is a 6-bit positive integer, M can be 2 for triple-level cells (TLC); if the weight data is a 9-bit positive integer, M can be 3 for TLC; if the weight data is a 16-bit positive integer, M can be 4 for quad-level cells (QLC).

In some implementations, the M memory strings containing the M memory cells storing the same weight data are all coupled to the same second sub-source region. It should be noted that each second sub-source region is also divided into multiple parts by the first isolation structures SLCUT1.

In some implementations, the segmentation of the source layer along the first direction is related to the data volume of the input data, i.e., the computational load per calculation. For example, if the input data scale is 32, the source layer can be segmented every 32 bit lines; if the input data scale is 64, the source layer can be segmented every 64 bit lines.

It can be understood that, in some implementations, the source layer can be adaptively segmented along the first direction based on the specifications of the input data. This prevents the wastage of bit lines and memory cells not used for data input, thereby enhancing the parallelism of the source layer's output.

In some implementations of the present disclosure, each of the multiple sub-source regions is connected to the analog-to-digital converter circuit 210 through the second bonding layer 102 and the fourth bonding layer 104.

In some implementations, when the source layer (common source) is not segmented, all memory strings within the same block are coupled via the source layer. As a result, the analog computation information output through the source layer corresponds to the analog computation information of that block. After the source layer is divided into multiple sub-source regions, it is equivalent to partitioning the common source of the block into smaller sections. Thus, when the source end serves as the analog information output end of the memory array, the analog computation information can be output in a partitioned manner through each sub-source region. That is, each sub-source region in the same block outputs one piece of analog computation information, and the multiple pieces of analog computation information output by the multiple sub-source regions collectively constitute the analog computation information of that block.

In some implementations of the present disclosure, the second semiconductor structure 300 further includes second interconnect structures 350 that extends through the memory array 301 and connects to the sub-source region 340. At least a portion of the peripheral circuit 302 is connected to the sub-source region through the third bonding layer 103, the first bonding layer 101, and the second interconnect structures 350. In a specific example, the second interconnect structures 350 can be through-array contacts (TAC). In some implementations, one end of the second interconnect structures 350 is connected to the source end via the sub-source region, while the other end is connected to the first bonding layer 101. Thus, the peripheral circuit 302 can be connected to the source end through the third bonding layer 103, the first bonding layer 101, the second interconnect structures 350, and the sub-source region.

In some implementations, each sub-source region is connected to the second interconnect structures 350, which is used to connect the corresponding sub-source region to the peripheral circuit. As a result, when the peripheral circuit receives an erase command, program command, or read command, it can output the corresponding control voltage to the sub-source region via the second interconnect structures 350. In a specific example, the peripheral circuit receives a program command from the controller through the second interface circuit and, in response, sends control signals to at least the row decoder/word line driver, column decoder/bit line driver, and voltage generator to initiate a programming operation on the selected memory cells.

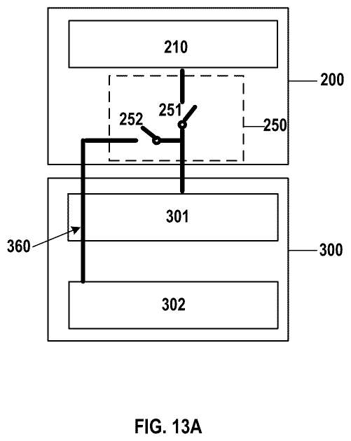

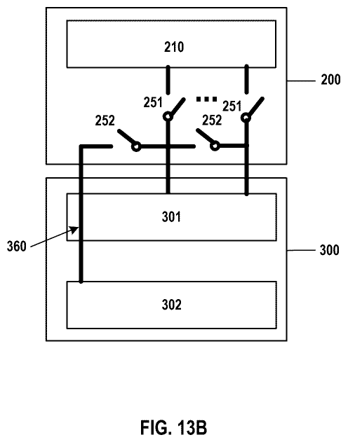

FIG. 13A is a fourth structural diagram of a semiconductor device according to one exemplary implementation of the present disclosure, and FIG. 13B is a fifth structural diagram of a semiconductor device according to one exemplary implementation of the present disclosure. It should be noted that FIG. 13A and FIG. 13B use the source end as the analog signal output end as an example for illustration.

Referring to FIG. 13A, the first semiconductor structure 200 further includes a switch control circuit. The switch control circuit includes a switch group 250 connected to the sub-source region through the fourth bonding layer and the second bonding layer. The switch group 250 comprises a first switch 251 and a second switch 252. One end of the first switch 251 is connected to the sub-source region, and the other end is connected to the analog-to-digital converter circuit 210. One end of the second switch 252 is connected to the sub-source region, and the other end is connected to the second sub-semiconductor structure through the fourth bonding layer and the second bonding layer.

In some implementations of the present disclosure, the second semiconductor structure 300 further includes third interconnect structures 360 that extend through the memory array 301 and connects to the sub-source region. At least a portion of the peripheral circuit 302 is connected to the sub-source region through the third bonding layer, the first bonding layer, the third interconnect structures 360, the second bonding layer, the fourth bonding layer, and the second switch 252.

In some implementations, under the computing-in-memory (CIM) architecture, since the semiconductor device simultaneously performs storage and computation functions, when the source end serves as the analog information output end of the memory array, the source layer needs to be connected to the peripheral circuit to implement the storage function and to the analog-to-digital converter circuit to implement the computation function. However, the source layer is positioned on the side of the memory array away from the peripheral circuit. Connecting multiple sub-source regions individually to the peripheral circuit would require a large number of interconnect structures (e.g., TACs). To address this, implementations of the present disclosure include a switch group in the first semiconductor structure connected to each sub-source region. The switch group controls whether the corresponding sub-source region is connected to the analog-to-digital converter circuit or the peripheral circuit, thereby reducing the need for numerous interconnect structures.

In some implementations, the second switch 252 is connected to the peripheral circuit 302 via the third interconnect structures 360. In some implementations, the third interconnect structures 360 can be through-array contacts (TAC) extending through the memory array. One end of each third interconnect structure 360 is connected to the second bonding layer, thereby connecting to the second switch 252 through the second bonding layer and the fourth bonding layer, while the other end is connected to the first bonding layer, thereby connecting to the peripheral circuit 302 through the first bonding layer and the third bonding layer. As a result, the peripheral circuit 302 can be connected to the second switch 252 through the third bonding layer, the first bonding layer, the third interconnect structures 360, the second bonding layer, and the fourth bonding layer.

In some implementations of the present disclosure, when the first switch is closed and the second switch is open, the sub-source region, second bonding layer, fourth bonding layer, and first switch form a signal transmission path between the source end and the analog-to-digital converter circuit. When the first switch is open and the second switch is closed, the third interconnect structures, second bonding layer, fourth bonding layer, second switch, and sub-source region form a signal transmission path between the second sub-semiconductor structure and the source end.

In some implementations, when the computation function is required, the first switch 251 is closed and the second switch 252 is open, allowing the source end to transmit analog computation information to the analog-to-digital converter circuit 210 through the signal transmission path formed by the sub-source region, second bonding layer, fourth bonding layer, and first switch 251. When the storage function is required, the first switch 251 is open and the second switch 252 is closed, enabling the peripheral circuit 302 to transmit control voltages to the source end through the signal transmission path formed by the third bonding layer, first bonding layer, third interconnect structures 360, second bonding layer, fourth bonding layer, second switch 252, and sub-source region.

In some implementations, each sub-source region is connected to its corresponding analog-to-digital converter circuit through a switch group, and the second switch of each switch group is connected to the peripheral circuit through third interconnect structures. In other words, the number of switch groups in the first semiconductor structure, the number of sub-source regions in the second semiconductor structure, and the number of third interconnect structures are all equal.

In some other implementations, the number of third interconnect structures 360 may be fewer than the number of switch groups (or sub-source regions), with multiple switch groups sharing a single third interconnect structures 360. For example, sub-source regions connected to the same bit line may share one third interconnect structures 360. This can reduce the number of third interconnect structures to some extent.

In still some other implementations, there may be only one third interconnect structure 360, meaning all switch groups corresponding to the same block share a single third interconnect structures 360. Referring to FIG. 13B, the second switches 352 of multiple switch groups are connected together and linked to the peripheral circuit 302 via one third interconnect structure 360. As a result, when all second switches are closed, the peripheral circuit 302 is connected to all sub-source regions (e.g., common source) through the third bonding layer, first bonding layer, third interconnect structure 360, second bonding layer, fourth bonding layer, and all second switches 252, thereby transmitting control voltages to the common source. This significantly reduces the number of third interconnect structures required.

In some implementations, the analog-to-digital conversion (ADC) circuit in the first semiconductor structure may specifically be a multi-bit analog-to-digital converter (multi-bit ADC), and the digital information output by the analog-to-digital conversion (ADC) circuit may include multiple bits (e.g., 4 bits, 8 bits, 12 bits, etc.). The analog-to-digital conversion (ADC) circuit converts the analog computation information into digital information and outputs it to the data processing circuit.

It should be noted that each sub-source region is connected to its corresponding analog-to-digital converter circuit through a switch group. In other words, the number of analog-to-digital conversion (ADC) circuits in the first semiconductor structure, the number of switch groups, and the number of sub-source regions in the second semiconductor structure are all equal. The multiple analog-to-digital conversion (ADC) circuits corresponding to the multiple sub-source regions collectively constitute the analog-to-digital conversion (ADC) circuit 210 of the first semiconductor structure 200.

In some implementations of the present disclosure, when there are multiple second semiconductor structures, the memory array of each second semiconductor structure is located between its corresponding peripheral circuit and the first semiconductor structure.

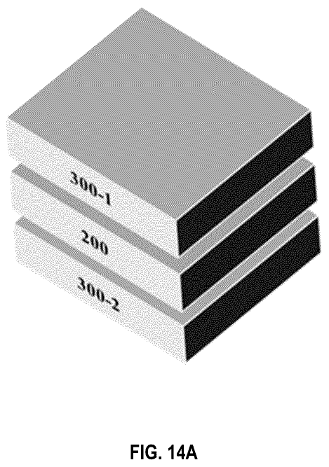

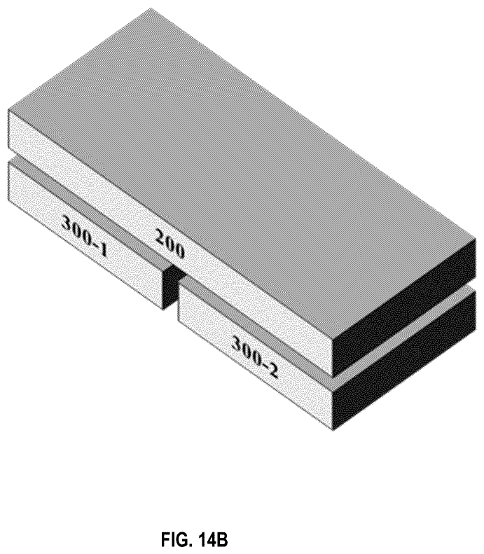

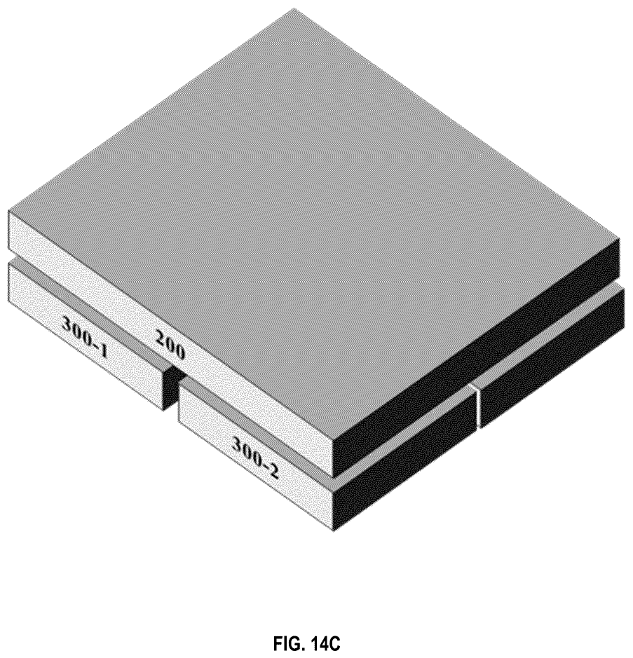

FIG. 14A is a sixth structural diagram of a semiconductor device according to one exemplary implementation of the present disclosure. Referring to FIG. 14A, when there are two second semiconductor structures, the two second semiconductor structures 300-1 and 300-2 are located on opposite sides of the first semiconductor structure 200, and the memory arrays of the two second semiconductor structures 300-1 and 300-2 are positioned between their corresponding peripheral circuit and the first semiconductor structure 200. That is, the first semiconductor structure 200 and the second semiconductor structures 300-1 and 300-2 are in different planes and stacked with respect to each other. When the planar sizes of the first semiconductor structure and the second semiconductor structures are similar, the stacking configuration shown in FIG. 14A can reduce the planar size of the semiconductor device.

FIG. 14B is a seventh structural diagram of a semiconductor device according to one exemplary implementation of the present disclosure. Referring to FIG. 14B, when there are two second semiconductor structures, the two second semiconductor structures 300-1 and 300-2 are located on the same side of the first semiconductor structure 200, and the memory arrays of the two second semiconductor structures 300-1 and 300-2 are positioned between their corresponding peripheral circuit and the first semiconductor structure 200. When the planar size of the first semiconductor structure is larger than that of the second semiconductor structures, the stacking configuration shown in FIG. 14B can reduce the stacking height of the semiconductor device.

FIG. 14C is an eighth structural diagram of a semiconductor device according to one exemplary implementation of the present disclosure. Referring to FIG. 14C, when there are four second semiconductor structures 300, the four second semiconductor structures 300-1, 300-2, 300-3, and 300-4 are all located on the same side of the first semiconductor structure 200, and the memory arrays of the four second semiconductor structures 300-1, 300-2, 300-3, and 300-4 are positioned between their corresponding peripheral circuit and the first semiconductor structure 200. When the planar size of the first semiconductor structure is significantly larger than that of the second semiconductor structures, the stacking configuration shown in FIG. 14C can reduce the stacking height of the semiconductor device.

In some implementations of the present disclosure, the semiconductor device may be implemented as devices such as a Universal Flash Storage (UFS) device, Solid State Drive (SSD), multimedia cards in the form of MMC, eMMC, RS-MMC, and micro-MMC, secure digital cards in the form of SD, mini-SD, and micro-SD, storage devices of the Personal Computer Memory Card International Association (PCMCIA) card type, storage devices of the Peripheral Component Interconnect (PCI) type, storage devices of the high-speed PCI (PCI-E) type, Compact Flash (CF) cards, smart media cards, or memory sticks. Specifically, the disclosed semiconductor devices can be applied to terminal products such as computers, televisions, set-top boxes, and in-vehicle systems.

Various implementations of the present disclosure also provide a computing-in-memory (CIM) device, comprising: a first semiconductor structure, including an analog-to-digital converter circuit and a data processing circuit; and a second semiconductor structure, including a memory array for performing a first operation and at least a portion of peripheral circuit coupled to the memory array. The first semiconductor structure and the second semiconductor structure are bonded together, and the memory array is located between the at least a portion of peripheral circuit and the second semiconductor structure.

In some implementations, the memory array is used to perform the first operation.

In some implementations, the analog-to-digital converter circuit is configured to convert analog computation information obtained from the first operation performed by the memory array into digital information; the data processing circuit is configured to perform a second operation on the digital information.

In some implementations, the second semiconductor structure includes a first sub-semiconductor structure on which the memory array is formed and a second sub-semiconductor structure on which at least a portion of the peripheral circuit is formed. The first sub-semiconductor structure includes a first bonding layer and a second bonding layer, with the memory array bonded to the second sub-semiconductor structure through the first bonding layer and bonded to the first semiconductor structure through the second bonding layer.

In some implementations, the memory array is located between the first bonding layer and the second bonding layer; the second sub-semiconductor structure includes a third bonding layer, which is bonded to the first bonding layer; the first semiconductor structure includes a fourth bonding layer, which is bonded to the second bonding layer.

In some implementations, the first bonding layer includes first bonding contacts and a first dielectric layer isolating the first bonding contacts, and the third bonding layer includes third bonding contacts and a third dielectric layer isolating the third bonding contacts; the first bonding contacts are bonded to the third bonding contacts, and the first dielectric layer is bonded to the third dielectric layer.

In some implementations, the second bonding layer includes second bonding contacts and a second dielectric layer isolating the second bonding contacts; the fourth bonding layer includes fourth bonding contacts and a fourth dielectric layer isolating the fourth bonding contacts; the second bonding contacts are bonded to the fourth bonding contacts, and the second dielectric layer is bonded to the fourth dielectric layer.

In some implementations, the analog-to-digital converter circuit is connected to the memory array through the fourth bonding layer and the second bonding layer and receives the analog computation information output by the memory array after performing the first operation via the fourth bonding layer and the second bonding layer.

In some implementations, the first sub-semiconductor structure further includes bit lines; the second semiconductor structure further includes first interconnect structures extending through the memory array and connecting to the bit lines and the second bonding layer; the memory array is connected to the analog-to-digital converter circuit through the bit lines, the first interconnect structures, the second bonding layer, and the fourth bonding layer.

In some implementations, the memory array includes multiple memory strings, each memory string including a drain end and a source end; the source end is connected to the analog-to-digital converter circuit through the second bonding layer and the fourth bonding layer.

In some implementations, the first sub-semiconductor structure further includes a source layer, with the source end connected to the source layer; the source layer is located on the side of the memory array near the second bonding layer; the source layer includes first isolation structures extending along the word line direction and a second isolation structures extending along the bit line direction, with the first isolation structures and the second isolation structures dividing the source layer into multiple sub-source regions.

In some implementations, each of the multiple sub-source regions is connected to the analog-to-digital converter circuit through the second bonding layer and the fourth bonding layer.

In some implementations, the second semiconductor structure further includes second interconnect structures extending through the memory array and connecting to the sub-source region; at least a portion of the peripheral circuit is connected to the sub-source region through the third bonding layer, the first bonding layer, and the second interconnect structures.

In some implementations, the first semiconductor structure further includes a switch control circuit, which includes switch groups connected to each sub-source region through the fourth bonding layer and the second bonding layer; each switch group includes a first switch and a second switch, with one end of the first switch connected to the sub-source region and the other end connected to the analog-to-digital converter circuit, and one end of the second switch connected to the sub-source region and the other end connected to the second sub-semiconductor structure through the fourth bonding layer and the second bonding layer.

In some implementations, the second semiconductor structure further includes third interconnect structures extending through the memory array and connecting to the sub-source region; at least a portion of the peripheral circuit is connected to the sub-source region through the third bonding layer, the first bonding layer, the third interconnect structures, the second bonding layer, the fourth bonding layer, and the second switch.

In some implementations, when the first switch is closed and the second switch is open, the sub-source region, second bonding layer, fourth bonding layer, and first switch form a signal transmission path between the source end and the analog-to-digital converter circuit; when the first switch is open and the second switch is closed, the third interconnect structures, second bonding layer, fourth bonding layer, second switch, and sub-source region form a signal transmission path between the second sub-semiconductor structure and the source end.

In some implementations, the first semiconductor structure further includes a first interface circuit and a controller; the first interface circuit is configured to output the computation results of the second operation performed by the data processing circuit to an external device, and the controller is used to control the second semiconductor structure to perform the first operation.

In some implementations, the second semiconductor structure further includes fourth interconnect structures extending through the memory array; one end of each fourth interconnect structure is connected to the second sub-semiconductor structure, and the other end is connected to the first interface circuit through the fourth bonding layer and the second bonding layer.

In some implementations, the second sub-semiconductor structure further includes a second interface circuit; the second semiconductor structure is also connected to the first semiconductor structure through the second interface circuit.

In some implementations, when there are multiple second semiconductor structures, the memory array of each second semiconductor structure is located between its corresponding peripheral circuit and the first semiconductor structure.

In some implementations, the first operation includes a multiply-accumulate operation.

In some implementations, the second operation includes one or more of compensation, activation, shift, or pooling operations.

In some implementations, the second semiconductor structure includes a three-dimensional NAND memory.

It is noted that, the specific structures and other details regarding the first semiconductor structure and the second semiconductor structure are similar to those in the aforementioned semiconductor device, which are not repeated herein for brevity.

Various implementations of the present disclosure also provide a semiconductor structure, including: a first sub-semiconductor structure and a second sub-semiconductor structure; the first sub-semiconductor structure includes a memory array for performing a first operation, and the second sub-semiconductor structure includes at least a portion of peripheral circuit; the first sub-semiconductor structure includes a first bonding layer and a second bonding layer, with the memory array bonded to the second sub-semiconductor structure through the first bonding layer, and the second bonding layer located on the side of the memory array away from the second sub-semiconductor structure, used for outputting the analog computation information after the memory array performs the first operation.

It is noted that, the specific structures and other details regarding the first sub-semiconductor structure and the second sub-semiconductor structure in the semiconductor structure are similar to those in the aforementioned semiconductor device, which are not repeated herein for brevity.

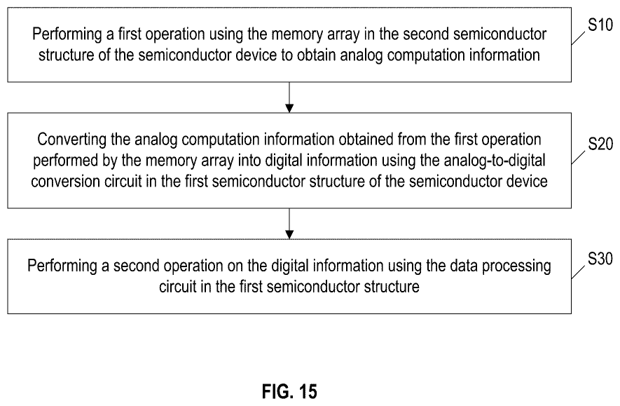

Based on a concept similar to the aforementioned semiconductor device, the present disclosure also provides an operation method for a semiconductor device. FIG. 15 is a flowchart schematic of the operation method of a semiconductor device, according to some implementations of the present disclosure. As shown in FIG. 15, the operation method of the semiconductor device includes the following steps:

Step S10: Performing a first operation using the memory array in the second semiconductor structure of the semiconductor device to obtain analog computation information, wherein the second semiconductor structure further includes at least a portion of peripheral circuit coupled to the memory array.

Step S20: Converting the analog computation information obtained from the first operation performed by the memory array into digital information using the analog-to-digital converter circuit in the first semiconductor structure of the semiconductor device, wherein the first semiconductor structure and the second semiconductor structure are bonded together.

Step S30: Performing a second operation on the digital information using the data processing circuit in the first semiconductor structure.

In some implementations, the first operation includes a multiply-accumulate operation.

In some implementations, the second operation includes one or more of compensation, activation, shift, or pooling operations.

In some implementations, the second semiconductor structure further includes a source layer coupled to the source end of the memory array, with the source layer divided into multiple sub-source regions. The first semiconductor structure further includes a switch control circuit, which includes switch groups connected to each sub-source region; each switch group includes a first switch and a second switch, where the first switch electrically controls signal transmission between the sub-source region and the analog-to-digital converter circuit, and the second switch electrically controls signal transmission between the sub-source region and at least a portion of the peripheral circuit. The method further includes: in response to an execution command for the first operation, controlling the first switch to close to output the analog computation information to the analog-to-digital converter circuit.

In some implementations, the method further includes: in response to an erase command, program command, or read command, controlling the second switch to close to output a control voltage to the sub-source region.

Based on the aforementioned semiconductor device, implementations of the present disclosure also provide a packaging structure, including: a packaging substrate, the semiconductor device described in any of the aforementioned implementations or the computing-in-memory (CIM) device described in the aforementioned implementations, and a molding layer; the semiconductor device or CIM device is disposed on the packaging substrate; the molding layer encapsulates the semiconductor device or CIM device.

In some implementations, the packaging substrate includes a base layer (e.g., a substrate) and a redistribution layer (e.g., an interposer) formed on the base layer, with connection circuits formed within the redistribution layer; the semiconductor device or CIM device is disposed on the side of the redistribution layer facing away from the base layer.

Based on the aforementioned semiconductor device, implementations of the present disclosure also provide an electronic device, including: the semiconductor device described in any of the aforementioned implementations or the CIM device described in the aforementioned implementations.

It is noted that, the specific structure of the semiconductor device refers to the aforementioned implementations. Since this electronic device adopts all the technical solutions of all the aforementioned implementations, it at least possesses all the beneficial effects brought by the technical solutions of the aforementioned implementations, which are not repeated herein one by one for brevity.

In some implementations, the electronic device may further include a host, where the host can be a processor of the electronic device, such as a Central Processing Unit (CPU) or a System on Chip (SoC), wherein the System on Chip may, for example, be an Application Processor (AP).

In some implementations, the aforementioned electronic device may be any device capable of storing data, such as a mobile phone, desktop computer, tablet computer, laptop computer, server, in-vehicle device, wearable device, or portable power bank.

It should be understood that the references to “some implementations” or “some implementations of the present disclosure” throughout the present disclosure mean that specific features, structures, or characteristics related to the implementations are included in at least one implementation of the present disclosure. Therefore, the phrases “in some implementations” or “in some implementations of the present disclosure” appearing in various parts of the specification do not necessarily refer to the same implementations. Furthermore, these specific features, structures, or characteristics may be combined in any suitable manner in one or more implementations. It should be understood that, in the various implementations of the present disclosure, the numerical order of the steps described above does not imply the sequence of execution; the execution order of each step should be determined by its function and inherent logic, and should not impose any limitation on the implementation process of the implementations of the present disclosure. The numerical order of the implementations of the present disclosure mentioned above is merely for descriptive purposes and does not indicate the superiority or inferiority of the implementations. The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents.

Although specific configurations and arrangements are discussed, it should be understood that this is done for illustrative purposes only. As such, other configurations and arrangements can be used without departing from the scope of the present disclosure. Also, the subject matter as described in the present disclosure can also be used in a variety of other applications. Functional and structural features as described in the present disclosures can be combined, adjusted, modified, and rearranged with one another and in ways that are consistent with the scope of the present disclosure.

What is claimed is:

1. A semiconductor device, comprising:
a first semiconductor structure comprising an analog-to-digital converter circuit and a data processing circuit; and
a second semiconductor structure comprising a memory array and a peripheral circuit coupled to the memory array;
wherein the analog-to-digital converter circuit is coupled with the memory array and configured to convert analog computation information based on a first operation performed by the memory array into digital information, and
the data processing circuit is coupled with the analog-to-digital converter circuit and configured to perform a second operation based on the digital information.

2. The semiconductor device of claim 1, wherein the second semiconductor structure comprises:
a first sub-semiconductor structure including the memory array; and
a second sub-semiconductor structure including the peripheral circuit;
the first sub-semiconductor structure and the second sub-semiconductor structure are bonded together.

3. The semiconductor device of claim 1, wherein the memory array is located between the first semiconductor structure and the peripheral circuit.

4. The semiconductor device of claim 1, wherein the first semiconductor structure is hybrid bonded with the second semiconductor structure.

5. The semiconductor device of claim 4, wherein the analog-to-digital converter circuit is coupled to the memory array through bonding contacts that interconnect the first semiconductor structure and the second semiconductor structure.

6. The semiconductor device of claim 5, wherein:
the first semiconductor structure further comprises bit lines;
the second semiconductor structure further includes first interconnect structures extending through the memory array and coupled with the bit lines; and
the memory array is coupled to the analog-to-digital converter circuit through the bit lines, the first interconnect structures, and the bonding contacts.

7. The semiconductor device of claim 5, wherein:
the first semiconductor structure further includes a source layer located between the memory array and the first semiconductor structure, and coupled to source ends of memory strings in the memory array; and
the memory array is coupled to the analog-to-digital converter circuit through the source layer and the bonding contacts.

8. The semiconductor device of claim 7, wherein:
the source layer includes isolation structures dividing the source layer into a plurality of sub-source regions; and
each of the plurality of sub-source regions is independently connected to the analog-to-digital converter circuit through at least one of the bonding contacts.

9. The semiconductor device of claim 8, wherein:
the isolation structures comprise first isolation structures each extending along a word line direction and second isolation structures each extending along a bit line direction.

10. The semiconductor device of claim 8, wherein:
the second semiconductor structure further includes second interconnect structures each extending through the memory array and connecting to a corresponding one of the plurality of sub-source regions; and
the peripheral circuit is coupled to the sub-source regions through the second interconnect structures.

11. The semiconductor device of claim 8, wherein:
the first semiconductor structure further comprises a switch control circuit comprising a plurality of switch groups each being coupled to a corresponding one of the plurality of the sub-source regions; and
each switch group comprises a first switch between the corresponding one of the plurality of the sub-source regions and the analog-to-digital converter circuit, and a second switch between the corresponding one of the plurality of the sub-source regions and the peripheral circuit.

12. The semiconductor device of claim 11, wherein the second semiconductor structure further includes third interconnect structures each extending through the memory array and coupled between the second switch and the peripheral circuit.

13. The semiconductor device of claim 12, wherein:
when the first switch is closed and the second switch is open, the first switch generates a signal transmission path between the corresponding one of the plurality of the sub-source region and the analog-to-digital converter circuit through at least one of the bonding contacts;
when the first switch is open and the second switch is closed, the second switch generates a signal transmission path between the corresponding one of the plurality of the sub-source region and the peripheral circuit through at least one of the third interconnect structures.

14. The semiconductor device of claim 1, wherein the first semiconductor structure further comprises:
a first interface circuit configured to output a computation result of the second operation performed by the data processing circuit; and
a controller configured to control the memory array to perform the first operation through the peripheral circuit.

15. The semiconductor device of claim 14, wherein:
the first sub-semiconductor structure further comprises fourth interconnect structures each extending through the memory array;
the second sub-semiconductor structure further comprises a second interface circuit coupled with the peripheral circuit; and
wherein the controller is coupled to the peripheral circuit through the first interface circuit, the fourth interconnect structures, and the second interface circuit.

16. The semiconductor device of claim 1, wherein:
a first lateral size of the analog-to-digital converter circuit is less than a second lateral size of the peripheral circuit; and
a bandwidth of the analog-to-digital converter circuit is at least 25 GB/s.

17. The semiconductor device of claim 1, further comprising:
two second semiconductor structures arranged laterally side by side; or
a plurality of second semiconductor structures arranged laterally in an array form.

18. The semiconductor device of claim 1, wherein:
the first operation comprises a multiply-accumulate operation; and
the second operation comprises one or more of compensation, activation, shift, or pooling operations.

19. A method for operating a semiconductor device, comprising:
performing a first operation by a memory array in a second semiconductor structure to obtain analog computation information, wherein the second semiconductor structure further includes a peripheral circuit coupled to the memory array;
converting the analog computation information obtained from the memory array performing the first operation into digital information using an analog-to-digital converter circuit in a first semiconductor structure, wherein the first semiconductor structure and the second semiconductor structure are bonded together;
performing a second operation based on the digital information using a data processing circuit in the first semiconductor structure.

20. A packaging structure, comprising:
a packaging substrate,
a semiconductor device disposed on the packaging substrate, the semiconductor device comprising:
a first semiconductor structure comprising an analog-to-digital converter circuit and a data processing circuit, and
a second semiconductor structure comprising a memory array and a peripheral circuit coupled to the memory array,
wherein the analog-to-digital converter circuit is coupled with the memory array and configured to convert analog computation information based on a first operation performed by the memory array into digital information, and
the data processing circuit is coupled with the analog-to-digital converter circuit and configured to perform a second operation based on the digital information; and
a molding layer encapsulates the semiconductor device.
